(19) United States
(12) Patent Application Publication
(10) Pub. No.: US 2008/0203552 A1
(43) Pub. Date: Aug. 28, 2008

(54) Stacked Package and Method of Fabricating the Same

(75) Inventors: Dong You Kim, Chungcheongbuk-do (KR); Ki Bon Cha, Chungcheiongbuk-do (KR)

Correspondence Address: DICKINSON WRIGHT PLLC, 1901 L. STREET NW, SUITE 800, WASHINGTON, DC, 20036, US

(73) Assignee: UNISEMICON CO., LTD., Kyeongki-do (KR)

(21) Appl. No.: 10/570,208

(22) PCT Filed: Mar. 8, 2005
(86) PCT No.: PCT/KR2005/000645

§ 371 Date: Apr. 8, 2008

(30) Foreign Application Priority Data
Feb. 15, 2005 (KR) 10-2005-0012297

(51) Int. Cl. H01L 23/488; H01L 21/56

(52) U.S. Cl. 257/686; 438/109; 257/E23.023; 257/E21.502

(57) ABSTRACT

Disclosed herein is a stacked package. The stacked package includes two or more of a first BGA package and a second BGA package and a circuit board having a circuit pattern. The first BGA package is mounted on one face of the circuit board, and the second BGA package is mounted on the other face of the circuit board. A signal connection member is provided for transmitting signals of the first BGA package and the second BGA package to each other. The second BGA package is provided with a signal connection pad. One end of the signal connection member is bonded to the signal connection pad and the other end of the signal connection member is bonded to the circuit pattern of the circuit board. A method of fabricating the stacked package is also disclosed.

### FIELD OF THE INVENTION

The present invention relates to a stacked package and a method of fabricating the same. In particular, the invention relates to a stacked package and a fabricating method thereof using a fine-pitch ball grad array semiconductor package (hereinafter, referred to as a “BGA package”), in which the signal length can be shortened and the height thereof can be minimized, thereby providing a high-speed stacked package and enabling a mass production therefor.

### BACKGROUND OF THE INVENTION

In general, a semiconductor element and a packaging technology therefor are closely related, and thus ceaseless attempts and efforts have been made in order to achieve a high-density, high-speed, miniaturized thin package. In particular, as the package structure has been changed into a surface-mounting mode from the pin-inserting mode, the mounting density of a circuit board has been dramatically improved.

Recently, a chip scale package (CSP) has been developed, which can be handled easily and has a reduced size, while, at the packed state, maintaining the characteristics of a bare chip.

Among those CSP packages, a BGA package has attracted most attentions. FIG. 1 is a cross-section showing the structure of a conventional BGA package.

As shown in FIG. 1, the BGA package 10 is composed of a semiconductor chip 1 having an electronic circuit integrated therein, a circuit board 2 for mounting the semiconductor chip 1, a wire 3 for electrically connecting the circuit board 2 with the semiconductor chip 1 to thereby transmit signals, an insulation material 5 molding the wire 3 for protection, and a solder ball 4 soldered to the bottom face of the circuit board 2 to thereby input and output signals.

Recently, a stacked package, which uses the above BGA package and has an increased capacity and packaging density, has attracted attentions. Dissimilar to a stacked chip package formed by stacking plural unpacked semiconductor elements, this stacked package is constructed by laminating plural unit packages, each which is assembled independently. A conventional stacked package is shown in FIGS. 2 and 3.

FIG. 2 is a cross-section showing the structure of a conventional stacked package fabricated using the BGA package of FIG. 1.

FIG. 2 shows a stacked package formed using a flexible printed circuit (FPC), which is a polyimide series film. The stacked package of FIG. 2 includes a first BGA package 10A, a second BGA package 10B, and a multi-layer film 12 connecting signals of the first and second BOA packages 10A, 10B. At the bottom face of the multi-layer film 12 is installed a solder ball 14 for transmitting signals to outside. Here, the first BGA package 10A and the second BGA package 10B are the same as that of FIG. 1.

In the process of fabricating the stacked package of FIG. 2, first, the second BGA package 10B is attached on the multi-layer film 12, and then an under fill is carried out such that the solder ball 14 provided in the second BGA package 10B does not move.

Thereafter, both sides of the film 12 is bent upward and attached to the top surface of the second BGA package 10B using an adhesive, and then on top thereof is mounted the first BGA package 10A, thereby completing a stacked package.

However, this stacked package embraces a problem in its reliability, which is caused by the joining between the first and second packages 10A and 10B and the polyimide film 12.

In addition, since the polyimide film 12 is assembled in two pieces, the assembling and treatment process is complicated to thereby increase the manufacturing cost thereof.

FIG. 3 is a cross-section showing another conventional stacked package formed of the BGA package of FIG. 1.

FIG. 3 shows a stacked package formed using a printed circuit board (PCB). The stacked package of FIG. 3 includes a first BGA package 10C, a second BGA package 10D, a first PCB 22A for connecting the signal of the first BGA package 10C, a second PCB 22B for connecting the signal of the second BGA package 10D, a third PCB 22C disposed between the first and second PCBs 22A, 22B and connecting the signals from them, and a solder ball 24 installed at the bottom face of the second PCB 22B. Here, the first and second BGA packages 10C, 10D are the same as that of FIG. 1.

In the manufacturing process for the stacked package of FIG. 3, first, the second BGA package 10D is placed on the top surface of the second PCB 22B and then an under fill is performed to thereby fix the solder ball. On the top surface of the third PCB 22C is mounted the third PCB 22C so as to enable a signal transmission.

In addition, after the first BGA PCB 10C is placed on the top surface of the first PCB 22A, an under fill is carried out to fix the solder ball so as not to move. Thereafter, the first PCB 22A with the first BGA package 10C placed thereon is laminated on the top surface of the third PCB 22C so as to enable a signal transmission. At the bottom face of the second PCB 22B is installed the solder ball 24 for transmitting signals to outside, thereby finishing the stacked package.

However, this stacked package has problems in that the first, second, third PCBs 22A, 22B, 22C cause an additional cost and the entire height of the package increases.

In addition, the first and second PCBs 22A and 22B are to be heat-bonded between the first BGA package 10C and the second BGA package 10D, thereby increasing the assembling cost thereof. Furthermore, the third PCB 22C is to be further installed beside the first and second PCBs 22A, 22B, and thus the size of the resultant stacked package increases disadvantageously.

Therefore, in the stacked package having the above-described construction, it needs a complicated fabricating process, the structure thereof is enlarged, and the signal connection line is extended. Furthermore, the second BGA package causes a trouble in heat-dissipating, thereby failing to apply to a stacked package for high speed.

Accordingly, the present invention has been made in order to solve the above problems occurring in the prior art, and it is an object of the invention to provide a stacked package and a method of fabricating the same, in which the entire height of a stacked package can be decreased and the signal length between packages can be shortened, thereby providing a stacked package for high speed.

In order to accomplish the above objects, according to one aspect of the invention, there is provided a stacked package including: two or more of a first BGA package and a second BGA package; a circuit board having a circuit pattern, the first BGA package being mounted on one face of the circuit board, the second BGA package being mounted on the other face of the circuit board; and a signal connection member for transmitting signals of the first BGA package and the second BGA package to each other, the second BGA package being provided with a signal connection pad, one end of the signal connection member being bonded to the signal connection pad and the other end of the signal connection member being bonded to the circuit pattern of the circuit board.

The signal connection member is provided with an insulation material coated in the entire periphery thereof.

The signal connection member is formed of a gold wire or a bent-formed conductive metallic lead.

The circuit board may be further provided with a signal connection-plating hole connected with a circuit pattern thereof, and the signal connection member is connected in such a way as to be inserted and bonded into the signal connection-plating hole.

According to another aspect of the invention, there is provided a stacked package including: two or more of a first BGA package and a second BGA package; a first circuit board having a circuit pattern, the first BGA package being mounted on one face of the first circuit board, the second BGA package being mounted on the other face of the first circuit board; a second circuit board having a circuit pattern, the second BGA package stacked in the first circuit board being surface-mounted on either face of the second circuit board; a signal connection member for transmitting signals of the first BGA package and the second BGA package to each other, both ends of the signal connection member being bonded to the respective circuit patterns of the first and second circuit boards; and a solder ball installed in the bottom surface of the second circuit board, for inputting and outputting signals of the first and second BGA packages.

The signal connection member is provided with an insulation material coated in the entire periphery thereof.

The signal connection member is formed of a gold wire or a bent-formed conductive metallic lead.

Either one or both of the first circuit board and the second circuit board may be further provided with a signal connection-plating hole connected with a circuit pattern thereof, and the signal connection member is connected in such a way as to be inserted and bonded into the signal connection-plating hole.

Two or more stacked packages having the above construction may be stacked in multi-layered form, and a signal connection connector for connecting signals of the layered stacked packages is installed between the stacked layers.

According to further aspect of the invention, there is provided a stacked package including: a first and second BGA package each having a circuit board, the circuit board having either a signal connection pad or a signal connection-plating hole each provided near an edge area thereof; and a signal connection member for transmitting signals of the first and second BGA packages which are stacked, the signal connection member being formed of a conductive metallic lead, the conductive metallic lead being bonded to the signal connection pad and being inserted and then bonded into the signal connection-plating hole so as to connect signals of the first and second BGA packages.

An insulation material is inserted between the stacked first and second BGA packages.

The conductive metallic lead is bent-formed so as to protrude upwards or downwards of the circuit board.

The signal connection member is installed in each of the first and second BGA packages, and the first and second BGA packages are stacked in such a manner that the signal connection members are bonded to each other to thereby transmit signals.

The above stacked package of the invention may further include a third circuit board installed in the lowest end of the stacked first and second BGA packages. The third circuit board includes a circuit pattern for transmitting signals of the first and second BGA packages and either one of a signal connection pad or a signal connection-plating hole to be connected with the circuit pattern. The signal connection pad or the signal connection-plating hole is connected with the signal connection member so as to transmit signals.

The third circuit board has a solder ball installed in the bottom surface thereof, for inputting and outputting signals of the first and second BGA packages.

According to a further aspect of the invention, there is provided a method of fabricating a staked package. The method includes the steps of: providing a second BGA package having a signal connection pad; providing a circuit board having a circuit pattern capable of connecting a signal of the second BGA package; placing an adhesive on one face of the circuit board and attaching the second BGA package at desired intervals; connecting the signal connection pad of the second BGA package with the circuit pattern of the circuit board using a signal connection member, the signal connection member being selected from a gold wire and a bent-formed conductive metallic lead; surface-mounting a first BGA package on the opposite face to the second BGA package in the circuit board so as to be connected with the circuit pattern thereof; and cutting the circuit board into each piece of stacked package.

The method of the invention may further include a step of coating an insulation material in the entire periphery of the signal connection member to thereby protect the signal connection member, after the above connecting step.

According to a further aspect of the invention, there is provided a method of fabricating a stacked package. The method of the invention includes the steps of: providing a second BGA package; providing a first circuit board having a circuit pattern capable of connecting a signal of the second BGA package; placing an adhesive on one face of the first circuit board and attaching the second BGA package at desired intervals; cutting into each piece the first circuit board having the second BGA packages attached thereto; providing a second circuit board having a circuit pattern capable of connecting a signal of the second BGA package, to which the first circuit board is attached; placing an adhesive on one face of the second circuit board and attaching at desired intervals the second BGA package, to which the first circuit board is attached; connecting the circuit patterns provided in the first and second circuit boards using a signal connection member, the signal connection member being selected from a gold wire and a bent-formed conductive metallic lead; surface-mounting a first BGA package on the first circuit board so as to be electrically connected with the circuit pattern thereof, the first circuit board having the second BGA package attached thereto; fusion-bonding a solder ball in the bottom surface of the second circuit board so as to enable a signal input/output; and cutting the second circuit board into each piece.

The above method of the invention may further include a step of coating an insulation material in the entire periphery of the signal connection member to thereby protect the signal connection member, after the above connecting step.

### SUMMARY OF THE INVENTION

As described above, according to the present invention, the height of a stacked package can be reduced and simultaneously shorten the signal length between BGA packages, thereby enabling the fabrication of high-speed stacked packages.

Furthermore, in the stacked package of the invention, a soldering can be carried out from outside, thereby enabling an easy fabrication and visual inspection, and also a mass production, which leads to reduction in the manufacturing cost.

### BRIEF DESCRIPTION OF THE DRAWINGS

Further objects and advantages of the invention can be more fully understood from the following detailed description taken in conjunction with the accompanying drawings in which:

FIG. 1 is a cross-section showing the structure of a conventional BGA package;

FIG. 2 is a cross-section showing the structure of a conventional stacked package fabricated using the BGA package of FIG. 1;

FIG. 3 is a cross-section showing another conventional stacked package formed of the BGA package of FIG. 1;

FIG. 4 is a cross-section illustrating a stacked package according to a first embodiment of the invention;

FIGS. 5 to 11 show a process for fabrication the stacked package of FIG. 4;

FIG. 12 is a cross-section illustrating a stacked package according to a second embodiment of the invention;

FIG. 13 is a cross-section illustrating a stacked package according to a third embodiment of the invention;

FIGS. 14 to 22 show a process for fabricating the stacked package of FIG. 13;

FIG. 23 is a cross-section illustrating a stacked package according to a fourth embodiment of the invention;

FIG. 24 is a cross-section illustrating a stacked package according to a fifth embodiment of the invention;

FIGS. 25 to 31 show a process for fabricating the stacked package of FIG. 24;

FIG. 32 is a cross-section illustrating a stacked package according to a sixth embodiment of the invention;

FIG. 33 is a cross-section showing a modification of the stacked package of FIG. 32;

FIG. 34 is a cross-section showing a stacked package according to a seventh embodiment of the invention;

FIG. 35 is a cross-section showing a modification of the stacked package of FIG. 34;

FIGS. 36 to 44 illustrate a process for fabricating the stacked package of FIG. 34;

FIG. 45 is a cross-section showing a stacked package according to an eighth embodiment of the invention;

FIG. 46 is a cross-section showing a modification of the stacked package of FIG. 45;

FIG. 47 is a cross-section illustrating a stacked package according to a ninth embodiment of the invention;

FIG. 48 is a cross-section of a stacked package according to a tenth embodiment of the invention;

FIGS. 49 to 52 are cross-sections each showing a modification of the stacked package of FIG. 48;

FIGS. 53 to 56 are cross-sections each illustrating a BGA package used for a stacked package according to an eleventh embodiment of the invention;

FIGS. 57 to 69 are cross-sections each illustrating a stacked package according to an eleventh embodiment of the invention, where the BGA packages of FIGS. 53 to 60 are used;

FIG. 70 is a cross-section showing a stacked package according to a twelfth embodiment of the invention;

FIGS. 71 to 83 are cross-sections each illustrating a modification of the stacked package of FIG. 70;

FIGS. 84 and 85 are cross-sections each showing a BGA package to be used for a stacked package according to a thirteenth embodiment of the invention;

FIGS. 86 to 89 are cross-sections each illustrating a stacked package according to an thirteenth embodiment of the invention, where the BGA packages of FIGS. 84 and 85 are used;

FIGS. 90 to 93 are cross-sections each showing a BGA package to be used for a stacked package according to a fourteenth embodiment of the invention;

FIGS. 94 to 91 are cross-sections each illustrating a stacked package according to a fourteenth embodiment of the invention, where the BGA packages of FIGS. 90 to 93 are used;

FIGS. 98 to 101 are cross-sections each showing a BGA package to be used for a stacked package according to a fifteenth embodiment of the invention;

FIGS. 102 to 105 are cross-sections each showing a stacked package according to a fifteenth embodiment of the invention, where the BGA packages of FIGS. 98 to 101 are used;

FIGS. 106 to 109 are cross-sections each showing a BGA package to be used for a stacked package according to a sixteenth embodiment of the invention; and

FIGS. 110 to 112 are cross-sections each showing a stacked package according to a sixteenth embodiment of the invention, where the BGA packages of FIGS. 106 to 109 are used.

### DETAILED DESCRIPTION OF THE PREFERRED EMBODIMENT

The preferred embodiments of the invention will be hereafter described in detail with reference to the accompanying drawings.

FIG. 4 is a cross-section illustrating a stacked package according to a first embodiment of the invention.

As shown in FIG. 4, the stacked package of the first embodiment is provided with a circuit board 110 having a circuit pattern for electrically connecting signals. On the top surface of the circuit board 110 is surface-mounted a first ball grid array (BGA) package 120 so as to enable to connect electrical signals, and at the bottom surface of the circuit board 120 is laminated a second BGA package 130 by using an adhesive.

The second BGA package 120 is provided with a signal connection pad 132 formed so as to be exposed when fabricating the second BGA package 130.

The signal connection pad 132 and the circuit pattern provided in the circuit board 110 are electrically connected by means Of a signal connection member 140. This signal connection member 140 may be formed of a lead wire, for example, a gold wire. In order to protect the gold wire, preferably, the bonding area of the gold wire is enclosed with an insulation material 150.

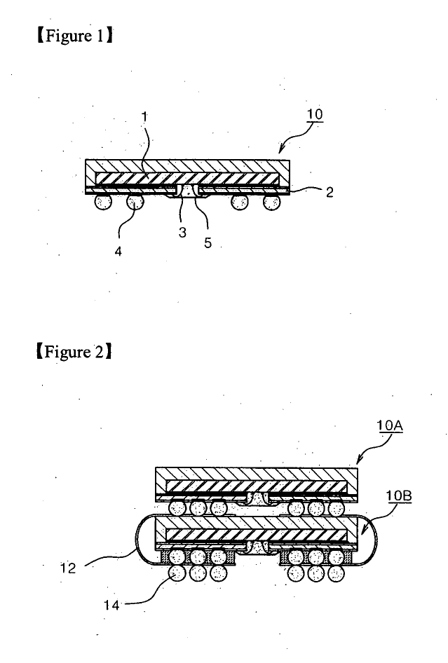

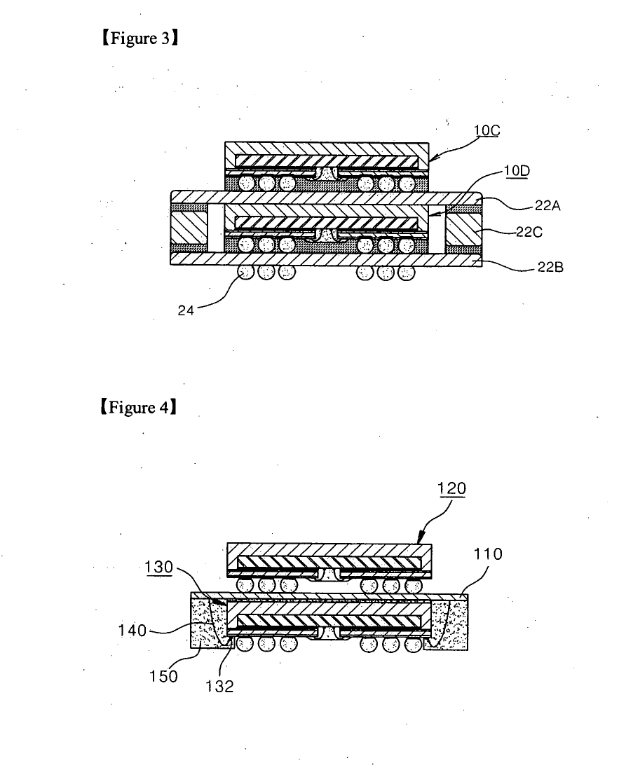

In the first embodiment, the first BGA package 120 has the same structure as that of the BGA package in FIG. 1. The second BGA package 130 has a configuration such that the signal connection pad 132 is further provided in the BGA package of FIG. 1. That is, the signal connection pad 132 is formed in such a way that, when a BGA package is fabricated, it is disposed adjacent to the edge area of the circuit board 2 (see FIG. 1) so as to bond a gold wire thereto.

In the stacked package according to the first embodiment of the invention, the first BGA package 120 surface-mounted on the top surface of the circuit board 110 is connected electrically with the circuit board 110 by means of a surface mounting. The second BGA package 130 laminated at the bottom surface of the circuit board 110 is electrically connected with the circuit board 110 by means of a gold wire. In this way, signals of the first and second BGA packages 120 and 130 are made to be transmitted.

In the stacked package of the first embodiment, the signal connection pad 132 provided in the second BGA package 130 contributes to reduce the thickness of the stacked package, and the signal connection pad 132 contributes to shorten the signal length, thereby enabling the fabrication of a stacked package for high speed.

In addition, according to the stacked package of the first embodiment, the soldering process is performed from outside. Thus, it allows an easy fabrication, visual inspection and mass production, thereby reducing the manufacturing cost thereof advantageously.

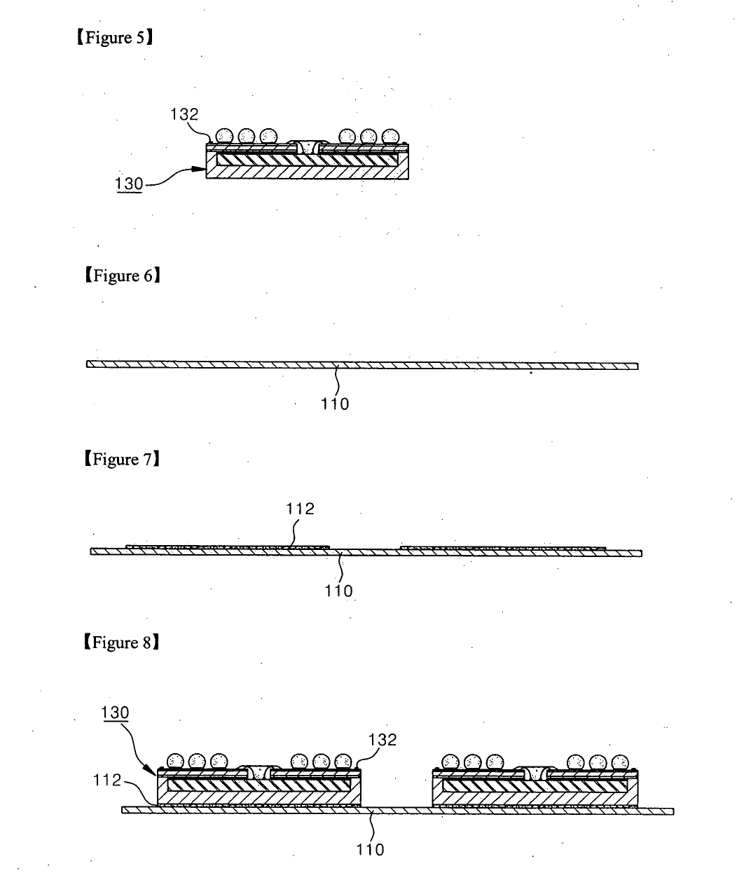

FIGS. 5 to 11 explain a process for fabrication the stacked package shown in FIG. 4.

Referring to FIG. 5, first, a second BGA package 130 having a signal connection pad 132 is prepared. The second BGA package 130 can be fabricated by providing the signal connection pad 132 when making the BGA package of FIG. 1, as described previously.

In addition, as shown in FIG. 6, a circuit board 110 is prepared such that the second BGA package 130 can be laminated thereon and simultaneously a circuit pattern provided so as to electrically connect signals of the second BGA package 130.

On the top surface of the circuit board 110 is applied an adhesive 112, as shown in FIG. 7. As shown in FIG. 8, the second BGA package 130 is attached to the circuit board 110.

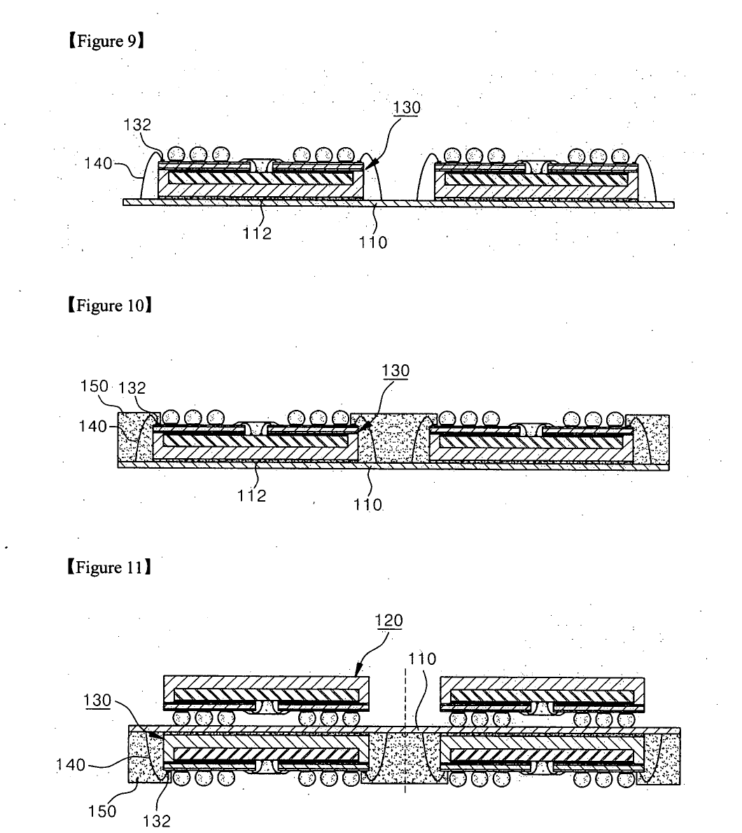

Thereafter, as shown in FIG. 9, the signal connection pad 132 provided in the second BGA package 130 is electrically connected with the circuit board 110 through a bonding using a gold wire, which is a signal connection member 140. As depicted in FIG. 10, the bonding area of the gold wire is enclosed in such a way to be embedded in an insulation material 150 to thereby protect the gold wire.

In addition, as illustrated in FIG. 11, a first BGA package 120 is surface-mounted on the opposite side to the second BGA package 130 in the circuit board 110 so as to be electrically connected. Then, the circuit board 110 is cut along the dotted line to thereby finish the manufacturing of the stacked package according to the first embodiment of the invention. Here, the first BGA package 120 shown in FIG. 11 is a common package, which does not have a signal connection pad and the same structure as that of FIG. 1.

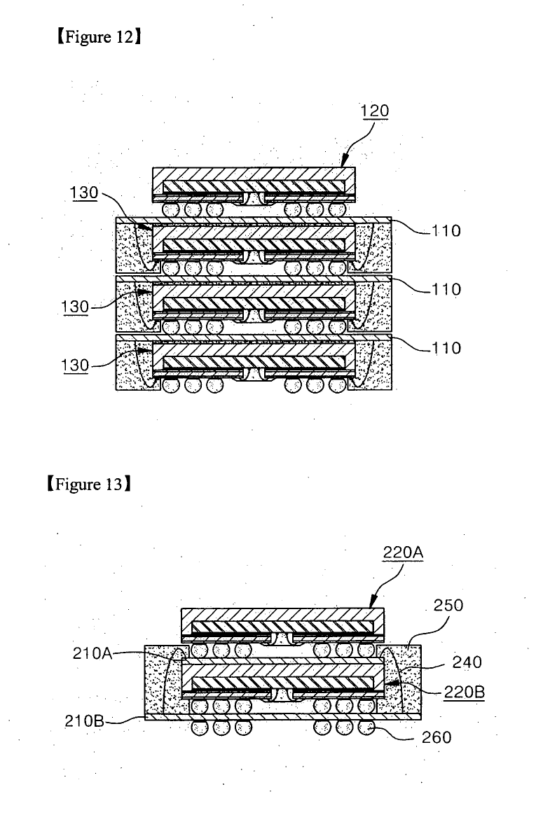

FIG. 12 is a cross-section showing a stacked package according to a second embodiment of the invention.

Referring to FIG. 12, in the stacked package of the second embodiment, the circuit board 110 and the second BGA package 130 attached at the bottom surface thereof are stacked in multiple layers and electrically connected by a surface mounting technique. Similarly, the circuit board 110 and the second BGA package 130 in each layer are electrically signal-connected by a gold wire bonding. That is, the first BGA package 120 of the first embodiment is mounted singularly, and the second BGA package and the circuit board 110 are laminated in multiple layers.

The manufacturing process of the stacked package of second embodiment will be described. In the first embodiment, the processes of FIGS. 5 to 10 are repeated and then the resultant plural products are stacked in a multi-layered form using a surface mounting so as to be electrically connected with one another. Thereafter, the process of FIG. 11 is carried out.

FIG. 13 is a cross-section of a stacked package according to a third embodiment of the invention.

As shown in FIG. 13, the stacked package of the third embodiment is provided with a first circuit board 210A formed so as to enable to connect electrical signals. On the top surface of the first circuit board 210A is mounted a first BGA package 220A through a surface mounting so as to be electrically connected, and on the bottom surface of the first circuit board 210A is attached a second BGA package 220B.

On the bottom surface of the second BGA package 220B is surface-mounted a second circuit board 210B so as to be electrically signal-connected. The first circuit board 210A and the second circuit board 210B are made to be electrically signal-connected through a signal connection member 240, which may be a gold wire.

In addition, an insulation material 250 such as a resin material encloses the bonding area of the gold wire to thereby protect the gold wire. On the bottom face of the second circuit board 210B is installed a solder ball 260, thereby enabling to input and output electrical signals through the solder ball.

The first and second BGA package 220A, 220B used in the stacked package of third embodiment have the same structure as the BGA package shown in FIG. 1.

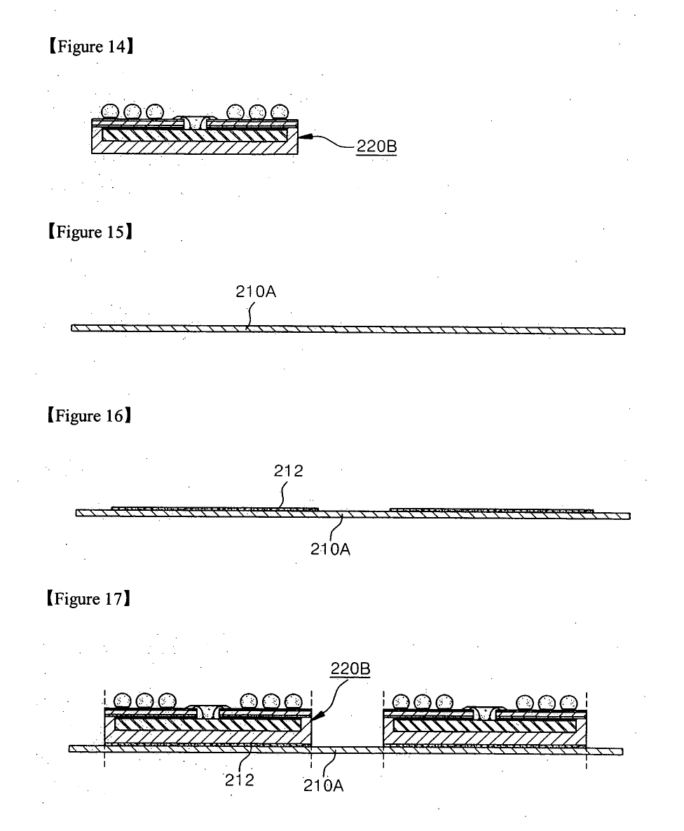

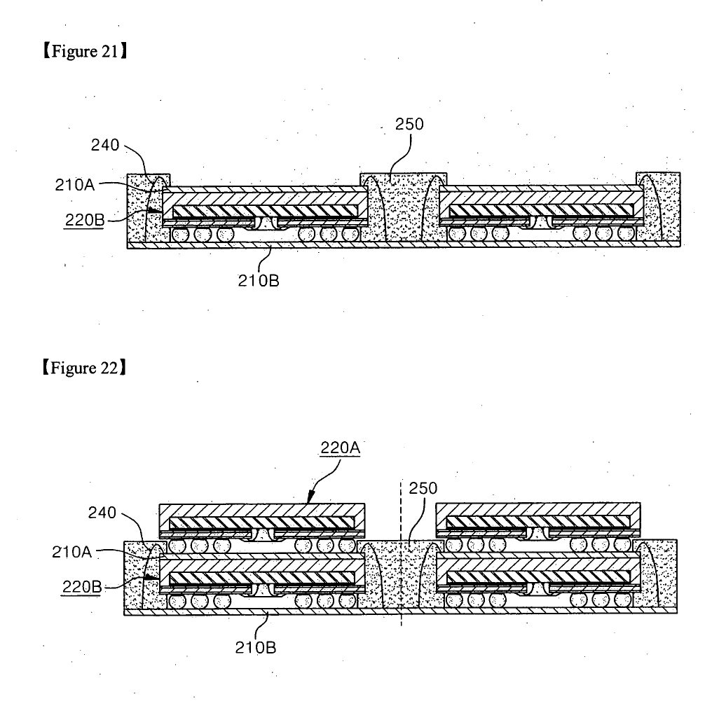

FIGS. 14 to 22 show a process for manufacturing the stacked package of FIG. 13.

FIG. 14 shows a second BGA package 220B having the same structure as the BGA package 10 of FIG. 1, and FIG. 15 depicts a first circuit board 210A. The first circuit board 210A is configured such that the second BGA package 220B can be stacked thereon and at the same time a signal of the second BGA package 220B is electrically connected.

Thereafter, as shown in FIG. 14, an adhesive 212 is placed on the top surface of the first circuit board 210A, and then the second BGA package 220B is attached to the circuit board 210A.

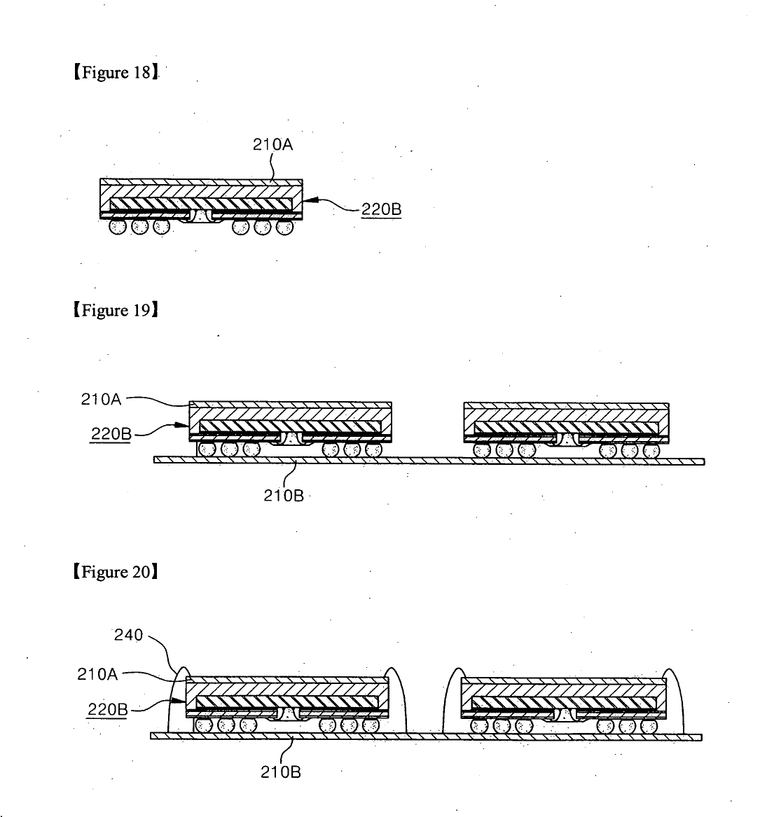

At this state, as shown in FIG. 18, a package, in which the second package 220B is bonded to the first circuit board 210A, can be obtained by cutting along an imaginary line in FIG. 17.

Referring to 19, the second BGA package 220B attached to the first circuit board 210A is surface-mounted on a second circuit board 210B so as to be electrically connected. The second circuit board 210B is configured so as to be electrically connected with the first circuit board 210A.

As depicted in FIG. 20, the first circuit board 210A and the second circuit board 210B are electrically connected through a gold wire bonding. As shown in FIG. 8h, the gold wire bonding area is enclosed with an insulation material 250 in such a way to be embedded therein, thereby protecting the gold wire.

Thereafter, as shown in FIG. 22, on the first circuit 210A attached the second BGA package 220B is stacked a new first BGA package 220A through a surface mounting so as to be electrically connected. The product of FIG. 22 can be divided into each piece by cutting along the dotted line in the figure.

Here, on the bottom of the second circuit board 210B is fusion-bonded a solder ball so as to allow input/output of electrical signals. At this time, the solder ball is preferred to be bonded before cutting the product of FIG. 22 into each piece.

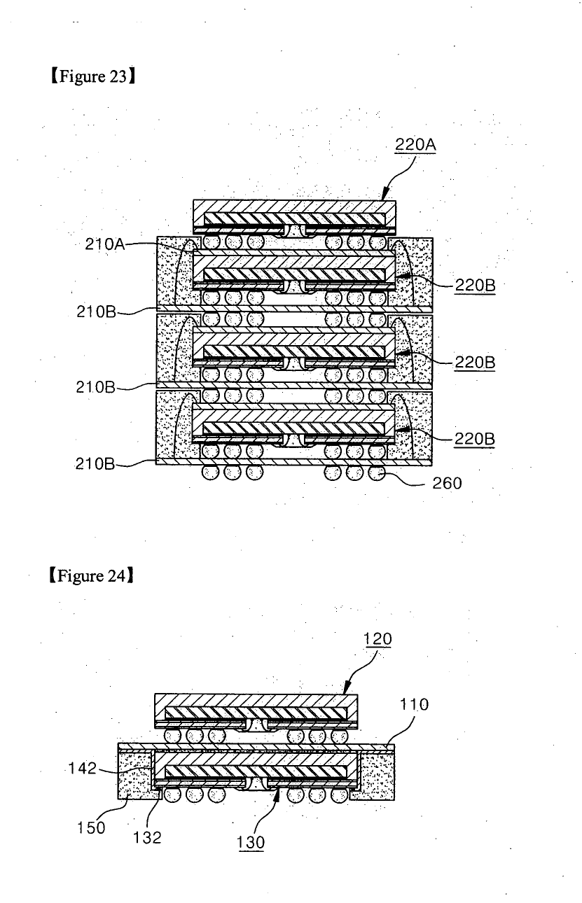

FIG. 23 is a cross-section showing a stacked package according to a fourth embodiment of the invention.

Referring to FIG. 23, the fourth embodiment forms a structure such that a combination of the first circuit board 210A, the second BGA package 220B and the second circuit board 210B is stacked in a multi-layered form through a surface mounting so as to connect an electrical signal. As in the third embodiment, the second circuit board 210B is signal-connected to the first circuit board 210A through a gold wire bonding, and on the bottom surface thereof is installed a solder ball 260.

The manufacturing process of the stacked package of fourth embodiment will be described. In the third embodiment, the processes of FIGS. 14 to 21 are repeated and then the resultant plural products are stacked in a multi-layered form, and a subsequent process is carried out to thereby finish the stacked package of FIG. 23.

FIG. 24 is a cross-section showing a stacked package according to a fifth embodiment of the invention.

As shown in FIG. 24, the fifth embodiment of the invention has a construction similar to the first embodiment. A difference from the first embodiment is in that, as a signal connection member 142, a bent conductive metallic lead is used, instead of a gold wire. Here, the conductive metallic lead is one kind of lead frames.

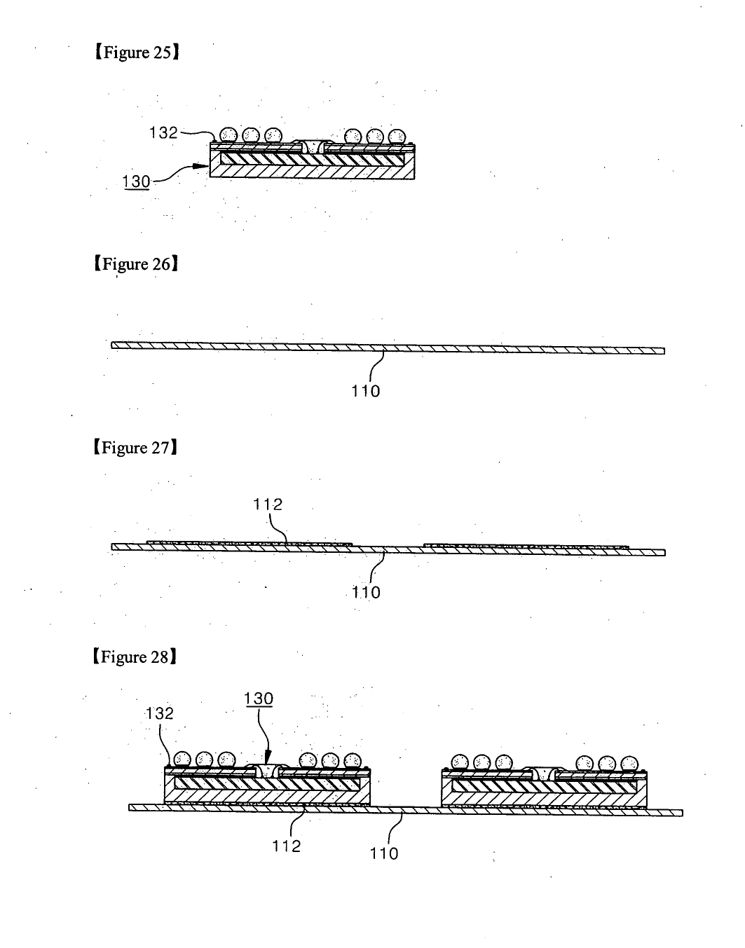

FIGS. 25 to 31 explain a process for fabricating the stacked package of FIG. 24.

The fabricating process illustrated in the figures is the same as that of the first embodiment, except that a bent conductive metallic lead is used for the connection of electrical signals, instead of using a gold wire bonding.

FIG. 25 shows a second BGA package 130 having a signal connection pad 132. FIG. 26 depicts a circuit board 110, which is configured such that the second BGA package 130 can be stacked thereon and at the same time a signal of the second BGA package 130 is electrically connected. As shown in FIG. 27, an adhesive 112 is placed on the top surface of the circuit board 110, and then the second BGA package 130 is attached to the circuit board 110, as shown in FIG. 28.

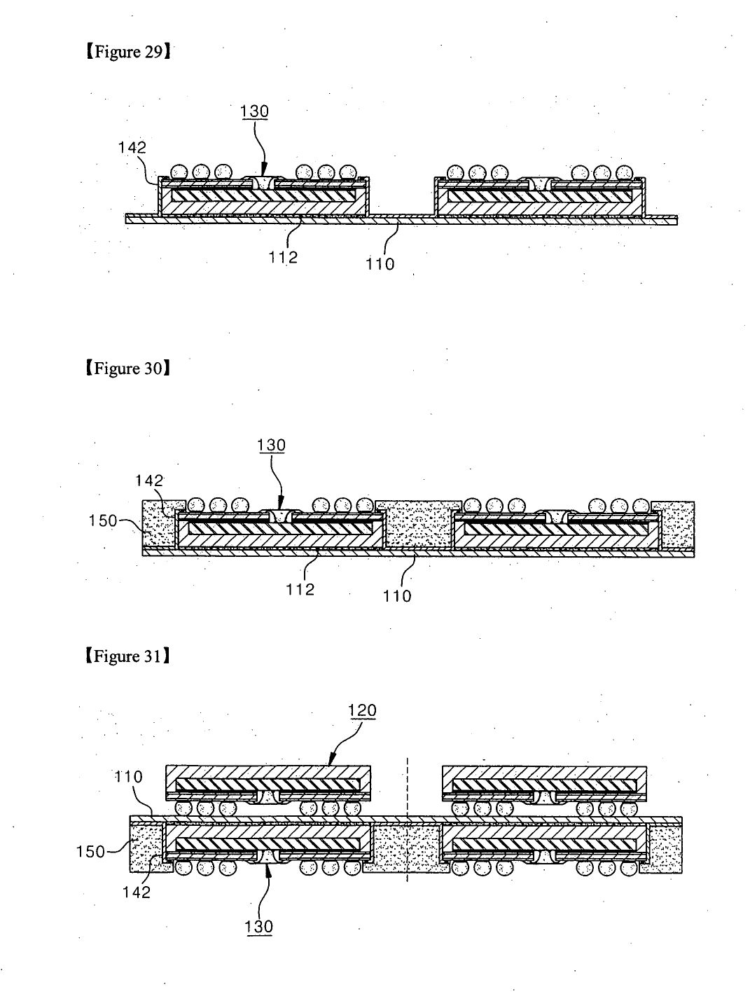

Then, as shown in FIG. 29, a signal connection member 142 is installed so as to electrically connect a signal connection pad 132 provided in the second BGA package 130 with the circuit board 110 for signal connection. The signal connection member 142 is a bent-formed conductive metallic lead, i.e., one type of a lead frame.

Referring to FIG. 30, the conductive metallic lead is enclosed with an insulation material 150 in order to protect the conductive metallic lead. Then, as shown in FIG. 11g, on the opposite side of the second BGA package 130 in the circuit board 110 is stacked a new first BGA package 120 through a surface-mounting so as to be electrical connected thereto. Here, the new first BGA package has the same structure as that of the BGA package described above, in conjunction with FIG. 1.

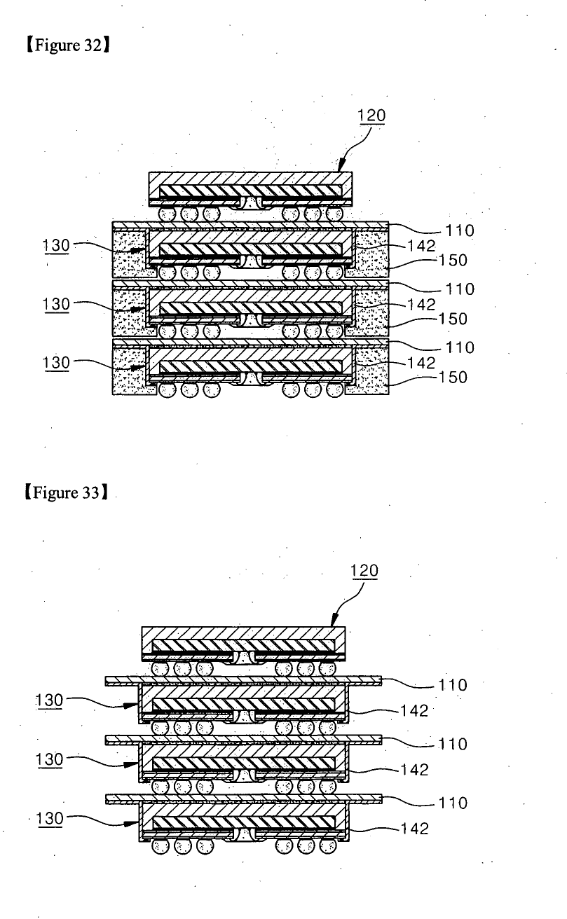

FIG. 32 is a cross-section illustrating a stacked package according to a sixth embodiment of the invention.

The stacked package of sixth embodiment is constructed in such a manner that, in the construction of the fifth embodiment, a combination of the second BGA package 130 and the circuit board 110 signal-connected thereto through the signal connection member 142, i.e., a bent-formed conductive metallic lead, is stacked in a multi-layered form.

FIG. 33 is a cross-section showing a modification of the stacked package of FIG. 32.

The modified embodiment of FIG. 13 has the same construction as in the sixth embodiment, except that the conductive metallic lead, i.e., the signal connection member 142 is not coated with an insulation material 150 of resin.

In addition, if the conductive metallic lead is plated, it does not need to be enclosed with an insulation material 150, and can be regarded as a lead frame used in a common semiconductor package.

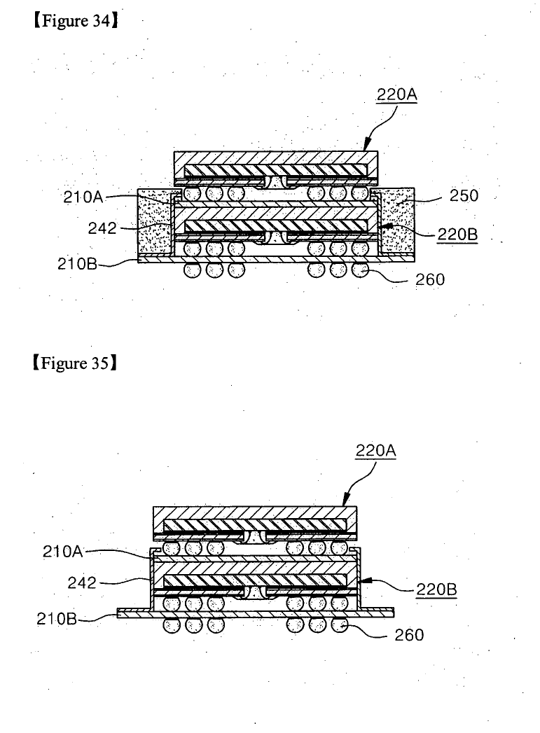

FIG. 34 is a cross-section showing a stacked package according to a seventh embodiment of the invention.

As shown in FIG. 34, the seventh embodiment of the invention has a construction similar to the third embodiment. A difference from the third embodiment is in that, as a signal connection member 142, a bent conductive metallic lead is used to electrically connect signals, instead of a gold wire. Here, the conductive metallic lead is one type of a lead frame.

FIG. 35 is a cross-section showing a modification of the stacked package of FIG. 34.

In this modified embodiment, the insulation material 250 of resin, which is provided in order to protect the signal connection member 242, i.e., the conductive metallic lead, is removed from the above stacked package according to the seventh embodiment. As described previously, removing of the insulation material 250 causes no harm.

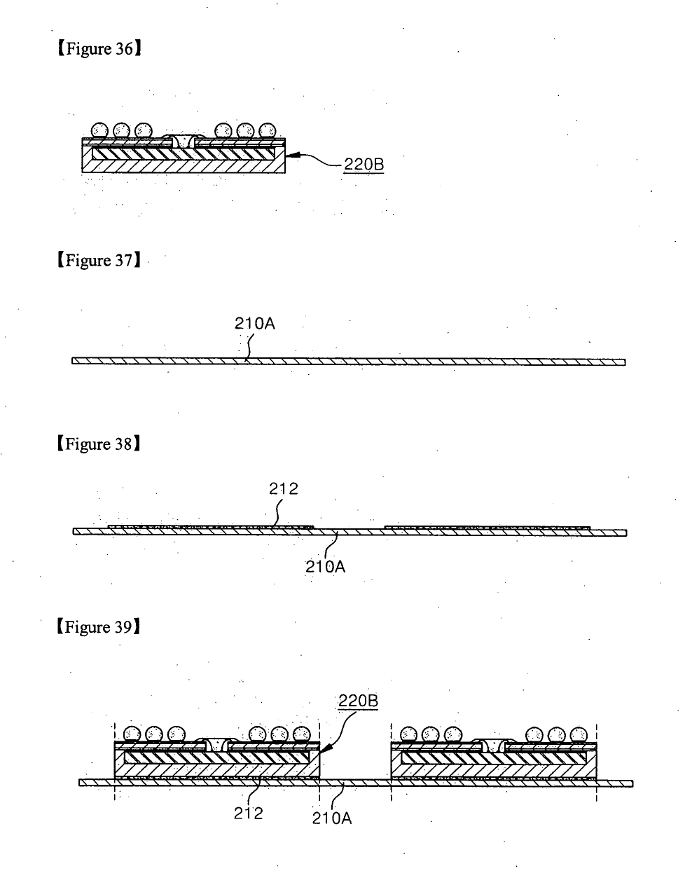

FIGS. 36 to 44 show a process for manufacturing the stacked package in FIG. 34.

The fabricating process illustrated in the figures is the same as that of the third embodiment, except that a bent conductive metallic lead is used for the connection of electrical signals, instead of using a gold wire bonding.

FIG. 36 shows a common second BGA package 220B. FIG. 37 depicts a first circuit board 210A, which is configured such that the second BGA package 220B can be stacked thereon and at the same time a signal of the second BGA package 220B is electrically connected.

As shown in FIG. 38, an adhesive 212 is placed on the top surface of the first circuit board 210A, and then the second BGA package 220B is attached to the first circuit board 210A, as shown in FIG. 39.

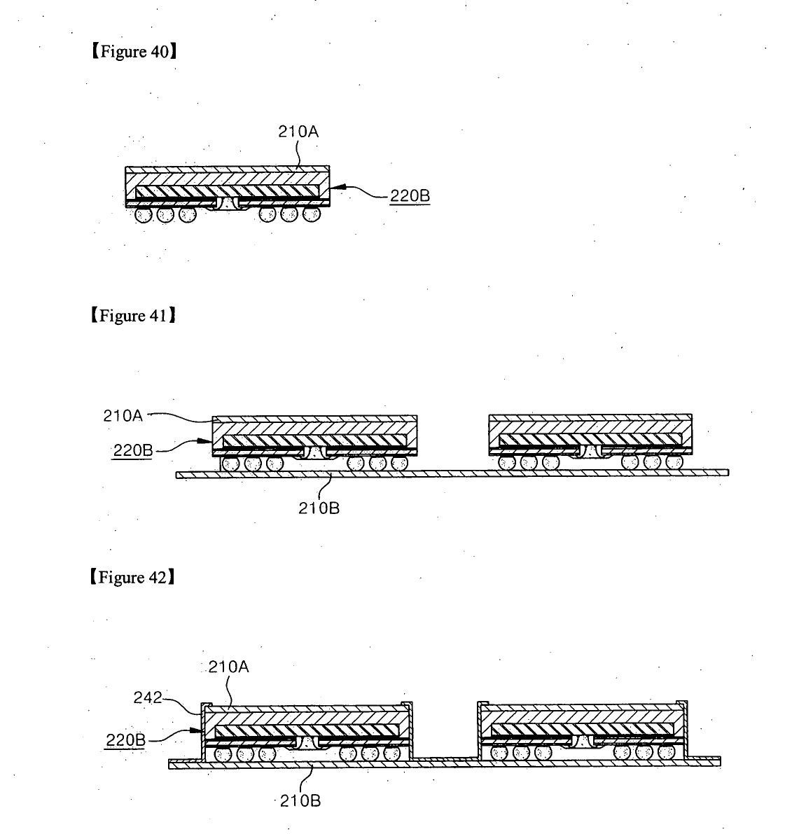

At this state, the product of FIG. 39 is cut along the imaginary line to thereby obtain a package shown in FIG. 40, in which a first circuit board 210A is attached to a second BGA package 220B.

Then, as shown in FIG. 41, the second BGA package 220B attached to the first circuit board 210A is surface-mounted on a new second circuit board 210B so as to be electrically connected. The second circuit board 210B is configured so as to be electrically connected with the first circuit board 210A.

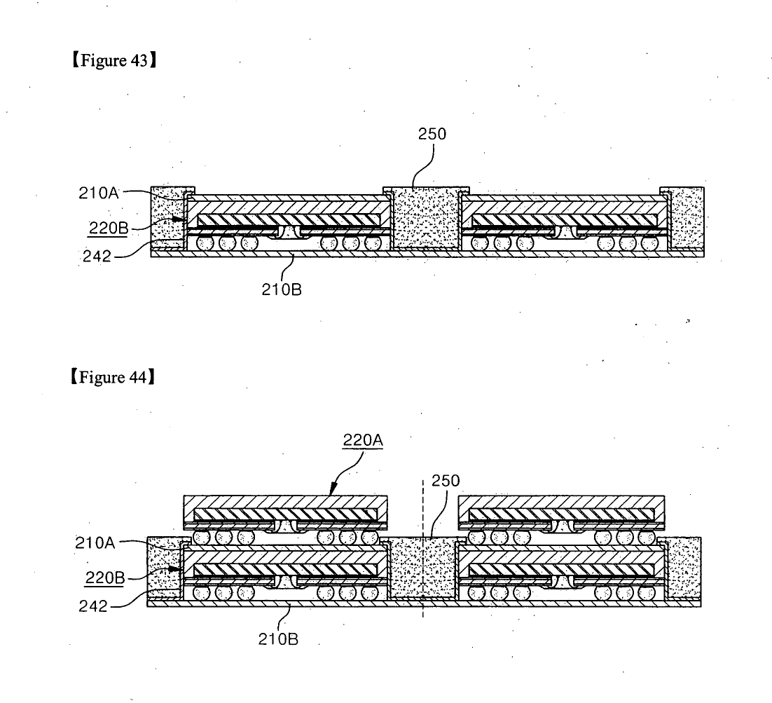

As depicted in FIG. 42, the first circuit board 210A and the second circuit board 210B are electrically connected through a bent-formed conductive metallic lead. As shown in FIG. 43, the conductive metallic lead is enclosed and coated with an insulation material 250 in such a way to be embedded therein, thereby protecting the conductive metallic wire.

Furthermore, as shown in FIG. 44, on the first circuit 210A attached to the second BGA package 220B is stacked a new first BGA package 220A through a surface mounting so as to be electrically connected. The product of FIG. 44 can be divided into each piece by cutting along the dotted line in the figure.

In addition, on the bottom surface of the second circuit board 210B is fusion-bonded a solder ball, thereby finishing a stacked package. The solder ball bonding is preferred to be performed before cutting into each piece.

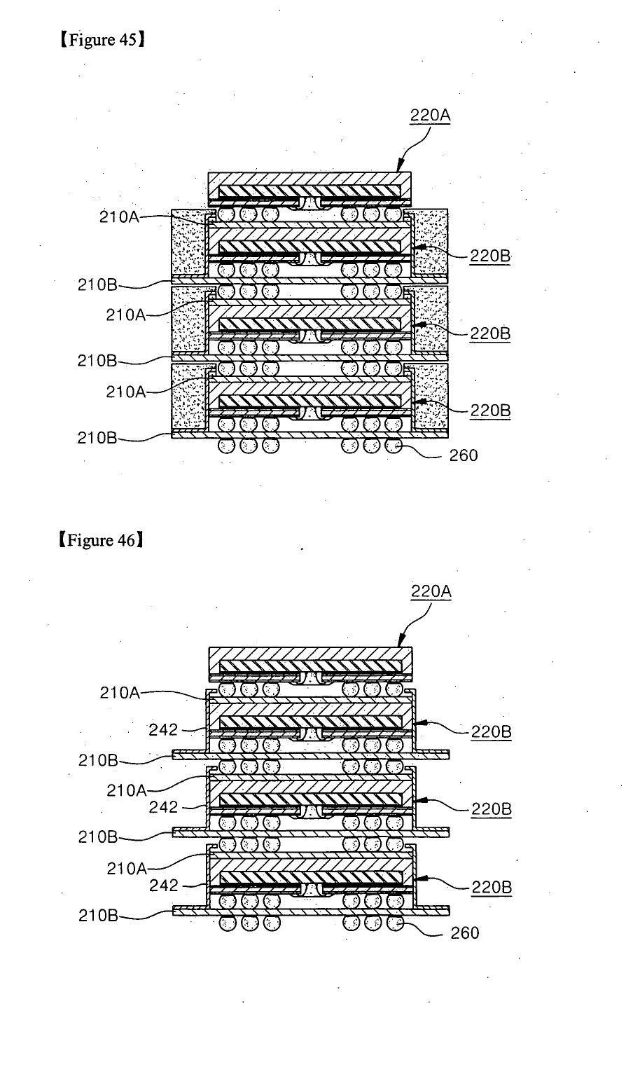

In this manufacturing process, the processes from FIGS. 36 to 43 are repeated and the resultant products are stacked in a multi-layered form, and a subsequent process is carried out to thereby fabricated a multi-layered stacked package, as illustrated in FIG. 45.

FIG. 45 is a cross-section showing a stacked package according to an eighth embodiment of the invention.

As shown in FIG. 45, the eighth embodiment of the invention has a construction similar to the fourth embodiment. A difference from the fourth embodiment is in that a conductive metallic lead is used to electrically connect signals, instead of a gold wire bonding.

FIG. 46 is a cross-section showing a modification of the stacked package of FIG. 45.

In this modified embodiment, the insulation material 250 is not coated, dissimilar to the eighth embodiment. The conductive metallic lead, which is a signal connection member, is not necessarily coated with an insulation material 250. Details thereon are described above and thus will be repeated here.

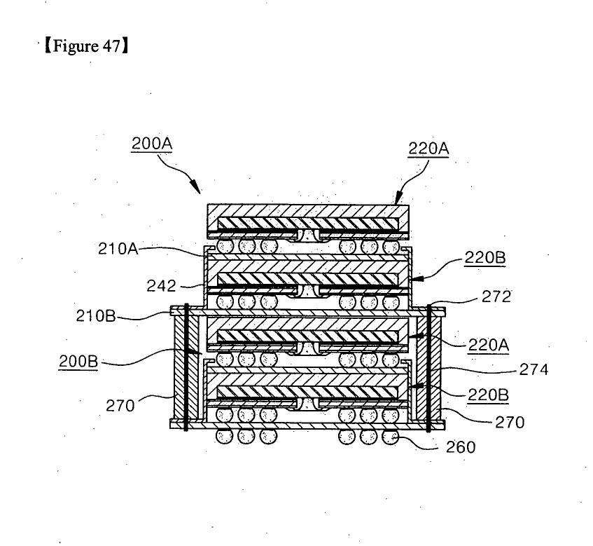

FIG. 47 is a cross-section showing a stacked package according to a ninth embodiment of the invention.

The stacked package of ninth embodiment in FIG. 47 is constructed in such a way as to stack the tacked package modified from the seventh embodiment in multiple layers using a signal connection connector 270.

As shown in FIG. 47, the ninth embodiment includes a first circuit board 210A constructed so as to enable to connect electrical signals, a first BGA package 220A surface-mounted on the top surface of the first circuit board 210A so as to connect electrical signals, a second BGA package 220B attached to the bottom surface of the first circuit board 210A, a second circuit board 210B disposed below the second BGA package 220B surface-mounted thereto so as to connect electrical signals, and a bent-formed conductive metallic lead electrically connecting the first circuit board 210A and the second circuit board 210B with each other, thereby consequently providing at least two stacked packages 200A and 200B. This stacked package 200A, 200B is the same as the modified stacked package of the seventh embodiment.

These stacked packages 200A and 200B are stacked, and then a signal connection connector 270 is further provided between the second circuit boards 210B formed in each stacked package 200A, 200B so as to connect electrical signals. On the bottom surface of the second circuit board 210B of a lowest stacked package is installed a solder ball 260 for inputting and outputting an electrical signal.

In order to install the signal connection connector 270, a signal transmission hole 272 is formed in the stacked packages 200A and 200B, and a pin 273 provided in the connection 270 is inserted and bonded into the hole 272 to thereby enable a signal connection.

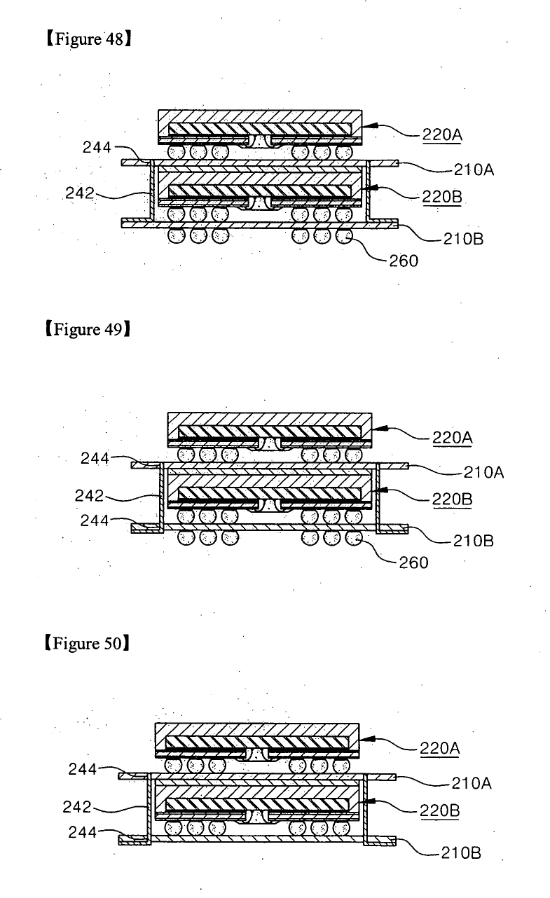

FIG. 48 is a cross-section showing a stacked package according to a tenth embodiment of the invention.

Referring to FIG. 48, in constructing the stacked package of the tenth embodiment, from the modified package of the seventh embodiment, the first circuit board 210A is made to have the same size as that of the second circuit board 210B in such a way as to be protruded outwards of the BGA packages. Then, a signal connection-plating hole 244 is further provided in either one or both of the first and second circuit boards 210A, 210B. Thereafter, a bent-formed conductive metallic lead, i.e., the signal connection member 242 is inserted and bonded into the plating hole 244 to thereby allow a signal connection.

The signal connection-plating hole 244 is formed in such a manner that a conductive material is plated along the inner circumferential face so as to be connected with a circuit pattern provided in the circuit boards 210A and 210B. Into the signal connection-plating hole 244 is inserted the conductive metallic lead, which is connected thereto by means of a soldering or the like so as to be signal-connected.

In the tenth embodiment having the above-described construction, in the first circuit board 210A is formed a signal connection-plating hole 244, into which the conductive metallic lead is inserted and soldered so as to allow a signal connection. Simultaneously, the conductive metallic lead is surface-mounted and soldered on the top surface of the second circuit board 210B to thereby connect signals. In addition, on the bottom face of the second circuit board 210B is installed a solder ball as an input/output terminal.

FIGS. 49 to 52 are cross-sections each illustrating a modification of the stacked package of FIG. 48.

FIG. 49 shows a first modified embodiment, in which the signal connection-plating hole 244 is formed in both of the first and second circuit board 210A, 210B and the conductive metallic lead is inserted and soldered into both side plating holes 244 to thereby allow a signal transmission. In addition, the conductive metallic lead is surface-mounted and soldered on the bottom surface of the second circuit board 210B, thereby enabling a more stable signal transmission.

FIG. 50 shows a second modified embodiment, in which the solder ball is removed from the bottom surface of the second circuit board 210B of the above first modified embodiment, and instead, the conductive metallic lead, which is surface-mounded and soldered on the bottom surface of the second circuit board 210B, made to serve as an input/output terminal.

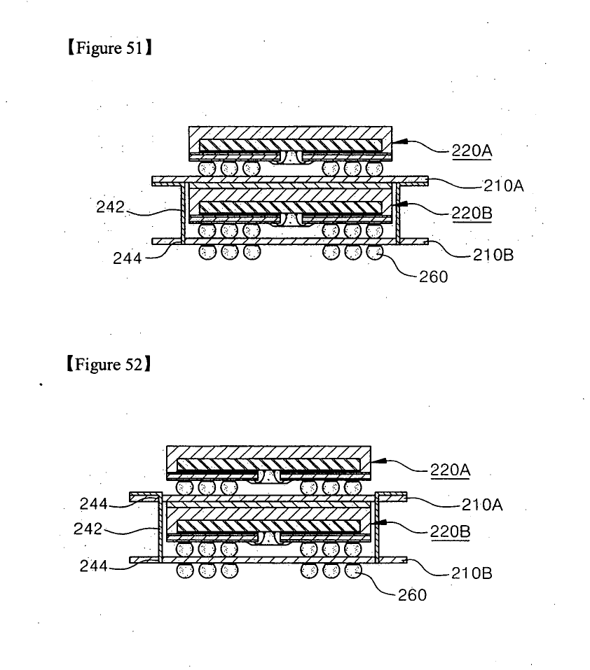

FIG. 51 shows a third modified embodiment. In this modified embodiment, a signal connection-plating hole 244 is formed in the second circuit board 210B, and the conductive metallic lead is inserted and soldered into the plating hole 244 to thereby provide a signal connection. On the bottom surface of the first circuit board 210A is a surface-mounted and soldered the conductive metallic lead so as to allow a signal transmission. In addition, on the bottom surface of the second circuit board 210B is installed a solder ball 260 as an input/output terminal.

FIG. 52 shows a fourth modified embodiment, in which the conductive metallic lead is surface-mounted and soldered on the top surface of the first circuit board 210A, dissimilar to the third modification where the conductive metallic lead is surface-mounted on the bottom surface of the first circuit board 210A.

According to the above modified embodiments, in the first circuit board 210A or the second circuit board 210B is formed a signal connection-plating hole 224. Then, the conductive metallic lead is passed through the signal connection-playing hole 244 for a signal connection, or is bent and surface-mounted to allow a signal transmission.

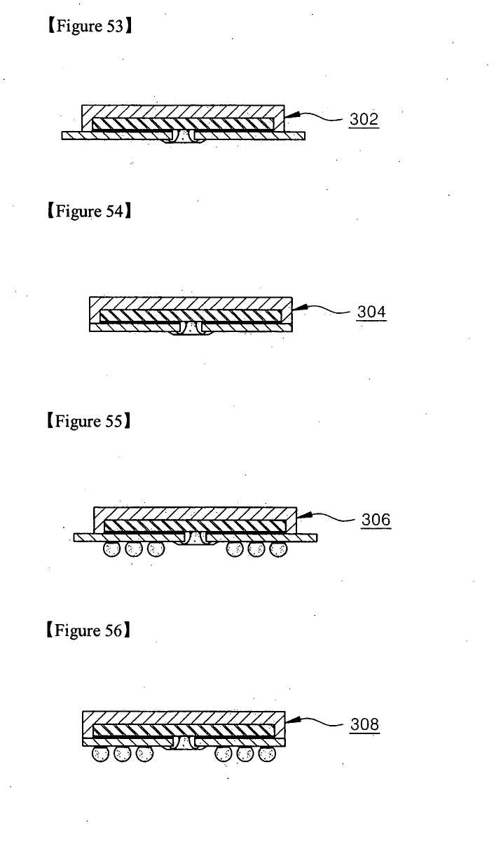

FIGS. 53 to 56 are cross-sections each showing a BGA package to be used in a stacked package according to an eleventh embodiment of the invention.

A BGA package 302 shown in FIG. 53 is constructed in such a way as to remove the solder ball from the BGA package of FIG. 1 and protrude the circuit board 2 outwards of the package body in the BGA package shown in FIG. 1. FIG. 54 shows a BGA package 304, in which the solder ball is removed from the BGA package of FIG. 1. A BGA package 306 of FIG. 55 is formed in such a way as to protrude the circuit board 2 outwards of the body of the BGA package in FIG. 1. A BGA package 308 of FIG. 56 has the same structure as that of the BGA package in FIG. 1.

The above BGA packages 302 to 308 are used for constructing a stacked package according to an eleventh and twelfth embodiment of the invention.

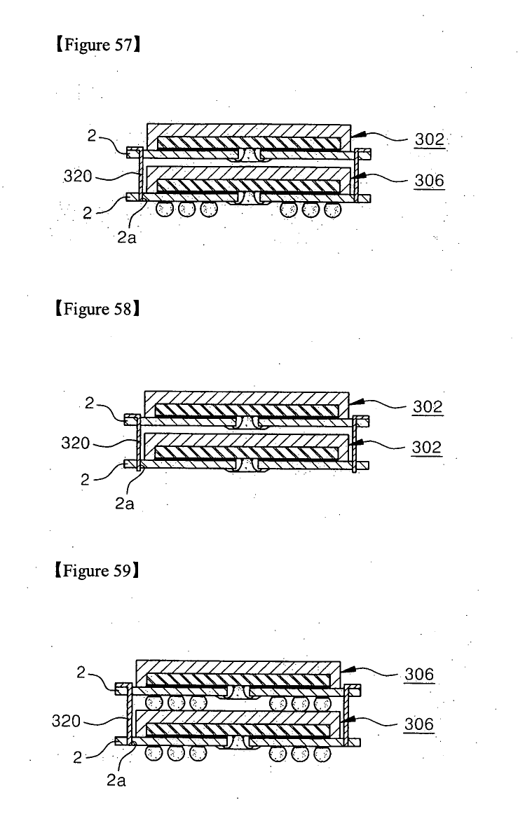

FIGS. 57 to 69 are cross-sections each showing a stacked package according to an eleventh embodiment of the invention, where the BGA packages of FIGS. 53 to 56 are used.

As illustrated in the figures, the stacked package of eleventh embodiment does not use a separate circuit board as explained previously, but uses a bent-formed signal connection member 320 only. The signal connection member 320 is a conductive metallic lead, which is one type of a lead frame.

In order to construct the above eleventh embodiment, a signal connection-plating hole 2a is further formed in the circuit board (see FIG. 1) provided in the BGA packages 302 to 308. Then, the signal connection member 320 is installed in the plating hole 2a to thereby connect the signals of the packages.

Here, the signal connection member 320 may be inserted and soldered into the signal connection-plating hole 2a, or may be mounted directly on the surface of the circuit board 2, in order to allow a signal transmission. The signal connection member 320 can be connected in various ways, as explained below in conjunction with FIGS. 57 to 69.

The stacked package of FIG. 57 is constructed in such a way that the BGA package 302 of FIG. 53 and the BGA package 306 of FIG. 55 are stacked, and in the circuit board 2 of the BGA packages 302 and 306 is formed respectively a signal connection-plating hole 2a, in which a signal connection member 320.

The signal connection member 320 is passed through the plating hole 2a and surface-mounted on the top surface of the circuit board 2 provided in the upper BGA package 302. That is, the signal connection member 320 is installed in such a way as to be inserted from the lower side towards the upper side of the stacked package.

In a stacked package shown in FIG. 58, two BGA package 302 of FIG. 53 are stacked, and the signal connection member 320 is installed in the same manner as in FIG. 57. However, the signal connection member 320 is installed so as to protrude downwardly through the plating hole 2a provided in the lower circuit board, so that the protruded portion can be served as an input/output terminal.

The stacked package of FIG. 59 is formed by stacking two BGA packages 304 of FIG. 55, and the signal connection member 320 is installed in the same way as in FIG. 57.

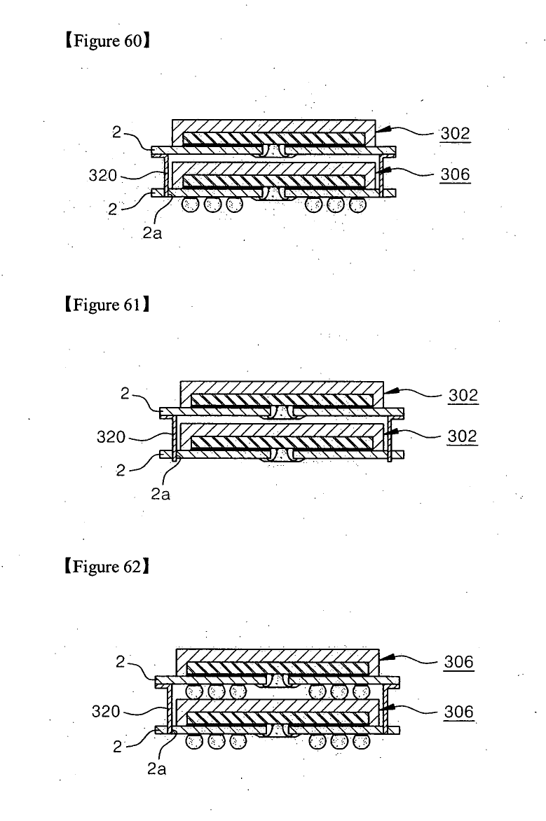

The stacked package of FIG. 60, is constructed in such a manner that the BGA package 302 of FIG. 53 and the BGA package 306 of FIG. 55 are stacked, and only in the circuit board 2 of the lower BGA package 306 is formed a signal connection-plating hole 2a, in which a signal connection member 320 is installed. The signal connection member 320 is surface-mounted on the bottom surface of the circuit board 2 of the upper BGA package 302 and at the same time is passed through the plating hole 2a provided in the circuit board 2 of the lower BGA package 306, thereby enabling a signal transmission.

In a stacked package shown in FIG. 61, two BGA packages 306 of FIG. 55 are stacked, and the signal connection member 320 is installed in the same way as in FIG. 60. However, the signal connection member 320 is passed through the plating hole 2a provided in the circuit board 2 of the lower BGA package 306 so as to be protruded downwardly, such that the protruded portion can be used as an input/output terminal.

The stacked package of FIG. 62 is formed by stacking two BGA packages 306 of FIG. 55, and the signal connection member 320 is installed in the same way as in FIG. 60.

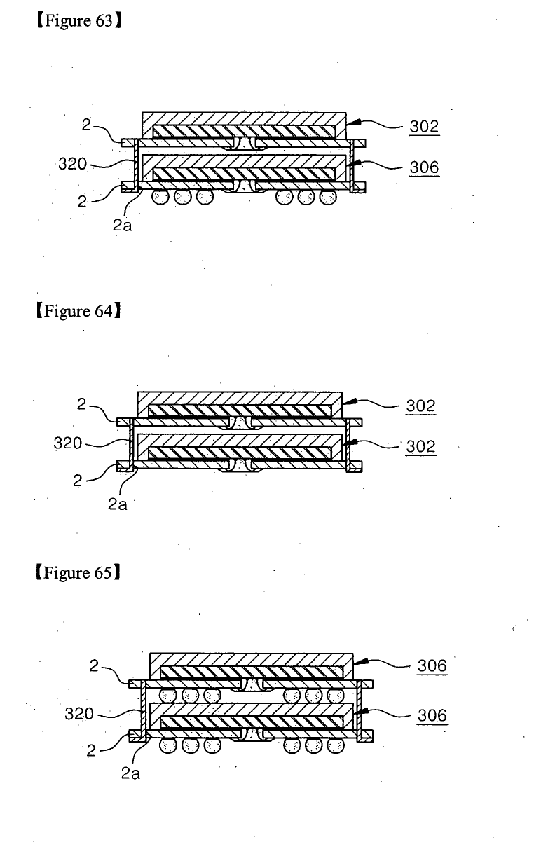

In a stacked package shown in FIG. 63, the BGA package 302 of FIG. 53 and the BGA package 306 of FIG. 55 are stacked, and in the circuit board 2 of the BGA packages 302 and 306 is formed respectively a signal connection-plating hole 2a where a signal connection member 320. The signal connection member 320 is surface-mounted on the bottom surface of the circuit board 2 provided in the lower BGA package 306 and simultaneously installed through the plating hole 2a. That is, the signal connection member 320 is installed in such a way as to be inserted from the lower side upwards of the stacked package.

The stacked package of FIG. 64 is formed by stacking two BGA packages 302 of FIG. 53, and the signal connection member 320 is installed in the same way as in FIG. 63. This stacked package does not have a solder ball installed on the bottom face thereof, and thus the signal connection member 320 is served as an input/output terminal.

The stacked package of FIG. 65 is formed by stacking two BGA packages 306, and the signal connection member 320 is installed in the same way as in FIG. 63.

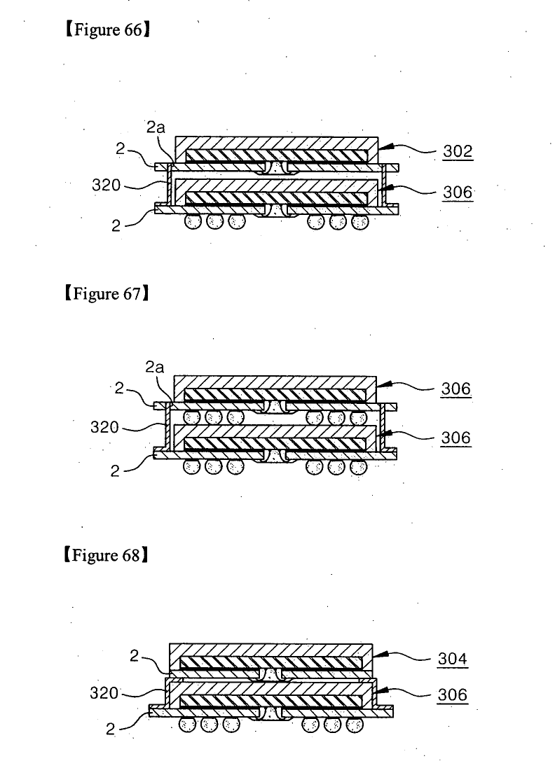

In a stacked package shown in FIG. 66, the BGA package 302 of FIG. 53 and the BGA package 306 of FIG. 55 are stacked. The signal connection member 320 is surface-mounted on the top surface of the circuit board 2 provided in the lower BGA package 306 and passes through the circuit board 2 of the upper BGA package 302.

The stacked package of FIG. 67 is constructed by stacking two BGA packages 306 of FIG. 55, and the signal connection member 320 is installed in the same manner as in FIG. 66.

In a stacked package shown in FIG. 68, the BGA package 304 of FIG. 54 and the BGA package of FIG. 55 are stacked. The signal connection member 320 is installed in such a manner that the lower portion thereof is bonded on the top surface of the circuit board of the lower BGA package 306, and the upper portion thereof is placed between the stacked packages 304 and 306 so as to enable to transmit signals from the upper BGA package 304.

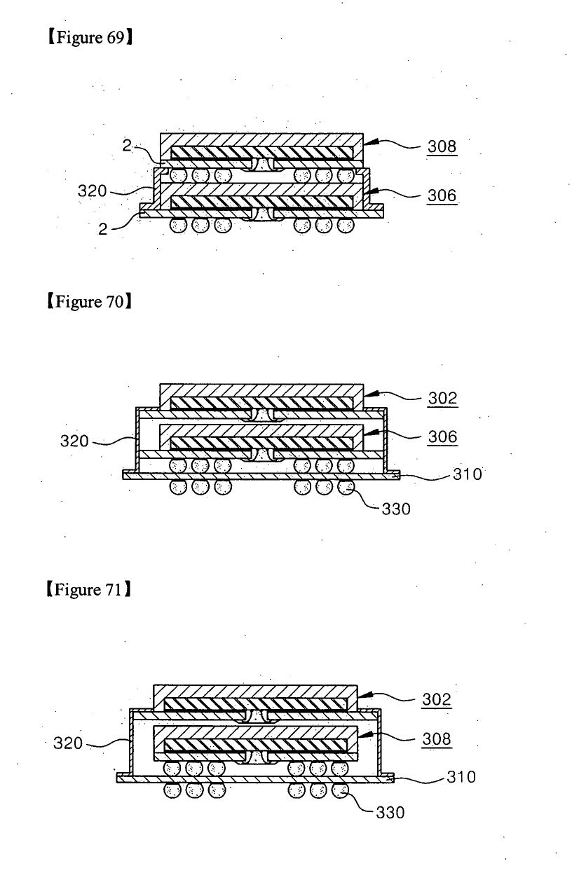

The stacked package of FIG. 69 is formed in such a way that the BGA package 306 of FIG. 55 and the BGA package 308 of FIG. 56 are stacked, and the signal connection member 320 is installed in the same way as in FIG. 68. Here, it is preferable that the signal connection member 320 is installed in such a way as to be in close contact with the outer peripheral surface of the lower BGA package 306.

In this way, besides the stacked packages illustrated in FIGS. 57 to 69, the BGA packages 302 to 308 of FIGS. 53 to 56 may be embodied into various other types of stacked package.

FIG. 70 is a cross-section showing a stacked package according to a twelfth embodiment of the invention.

In the stacked package according to the twelfth embodiment, the BGA packages 302 to 308 of FIGS. 53 to 56 are used to be stacked, and an additional third circuit board 310 is installed at the lowest position thereof. Then, a bent-formed signal connection member 320 is used for a signal connection. Here, the signal connection member 320 is a conductive metallic lead, which is one type of a lead frame.

Similar to the eleventh embodiment, the stacked package of twelfth embodiment is constructed in such a way that a signal connection-plating hole 2a is provided selectively in the third circuit board 310 and the circuit board 2 (see FIG. 1) provided in the BGA packages, and a bent-formed signal connection member 320 is utilized for a signal connection.

In the above stacked package according to the twelfth embodiment of the invention, it is preferable that a solder ball 330 for using as an input/output terminal is further installed on the bottom surface of the third circuit board 310.

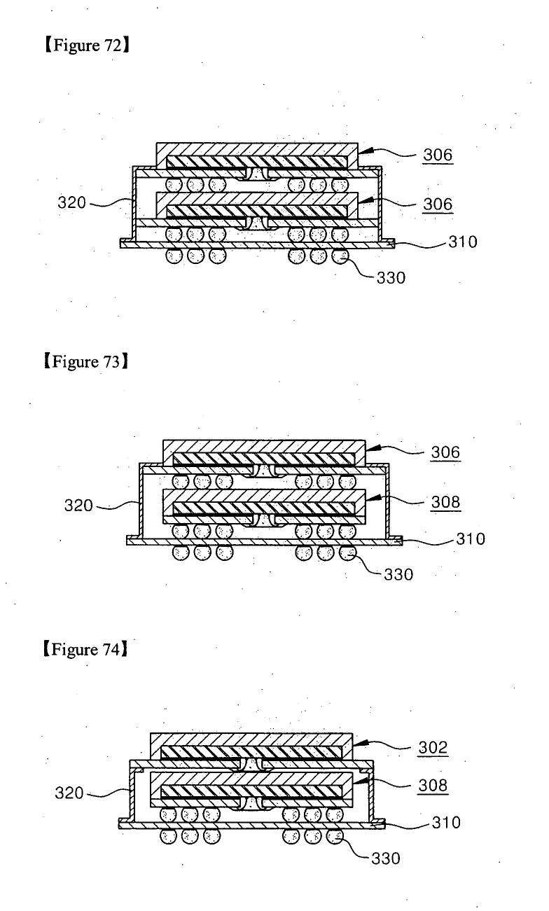

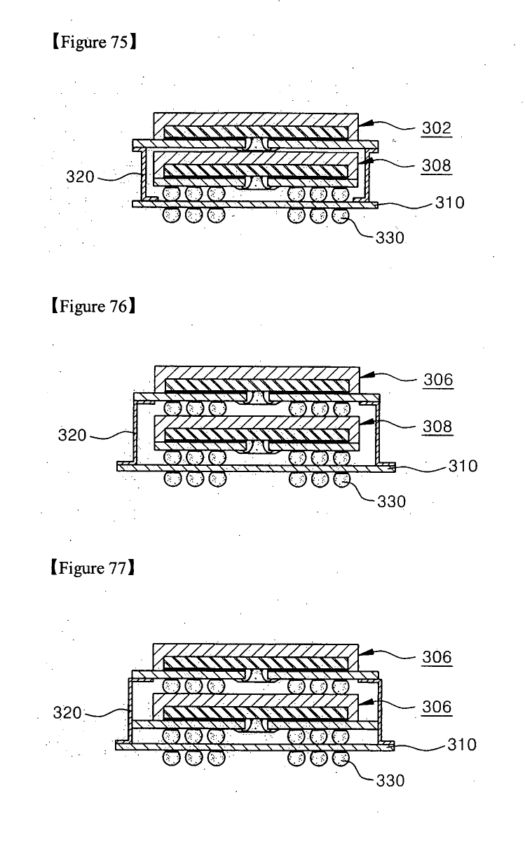

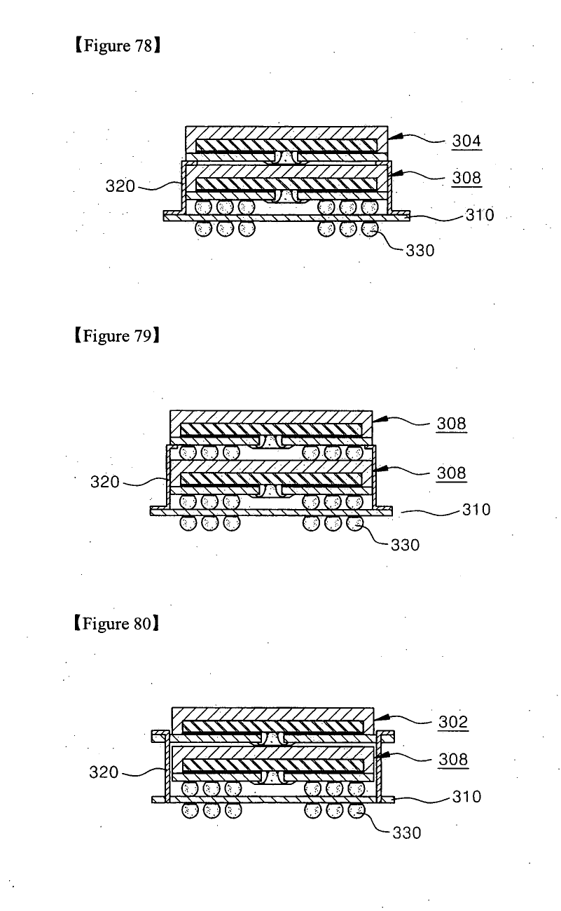

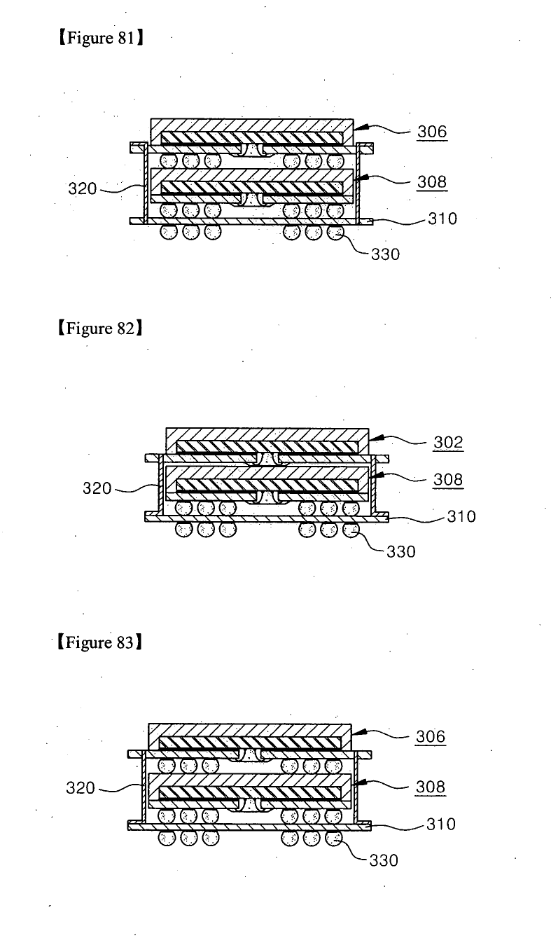

FIGS. 71 to 83 are cross-sections each showing a modification of the stacked package of FIG. 70.

The stacked packages shown in FIGS. 71 to 83 have a constitution similar to those of FIGS. 57 to 69. A difference is in that a third circuit board 310 is further provided at the lowest position of the stacked package. Details on each modified embodiment will not be repeated here.

Therefore, besides the twelfth embodiment and various modified embodiments, the BGA packages 302 to 308 of FIGS. 53 to 56 can be used to embody various other types of stacked packages, which are not shown in FIGS. 71 to 83.

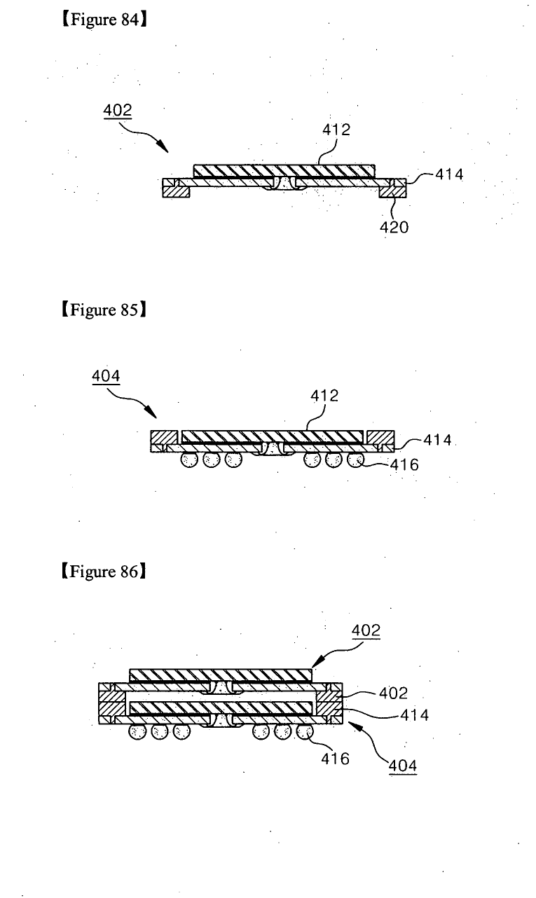

FIGS. 84 and 85 are cross-sections each showing a BGA package to be used in a stacked package according to a thirteenth embodiment of the invention.

FIGS. 84 and 85 illustrate a BGA package 402, 404 for using in a stacked package according to a thirteenth embodiment of the invention. The BGA package 402 of FIG. 84 includes a circuit board 414, a semiconductor chip 412 mounted on the circuit board 414, and a conductive metallic lead 420 installed near the edge area of the circuit board 414 so as to be protruded downwardly.

In addition, the BGA package 404 shown in FIG. 85 includes a circuit board 414, a semiconductor chip 412 mounted on the circuit board 414, a conductive metallic lead 420 installed near the edge area of the circuit board 414 so as to be protruded upwardly, and a solder ball 416, as an input/output terminal, installed in the bottom surface of the circuit board 414.

FIGS. 86 to 89 are cross-sections each showing a stacked package according to a thirteenth embodiment of the invention, where the BGA packages of FIGS. 84 and 85 are used.

The stacked package shown in FIG. 86 is formed by stacking the BGA package 402 of FIG. 84 and the BGA package 404 of FIG. 85. The signal connection is achieved by means of the conductive metallic leads 420 installed respectively in the top and bottom surface of the circuit board 414.

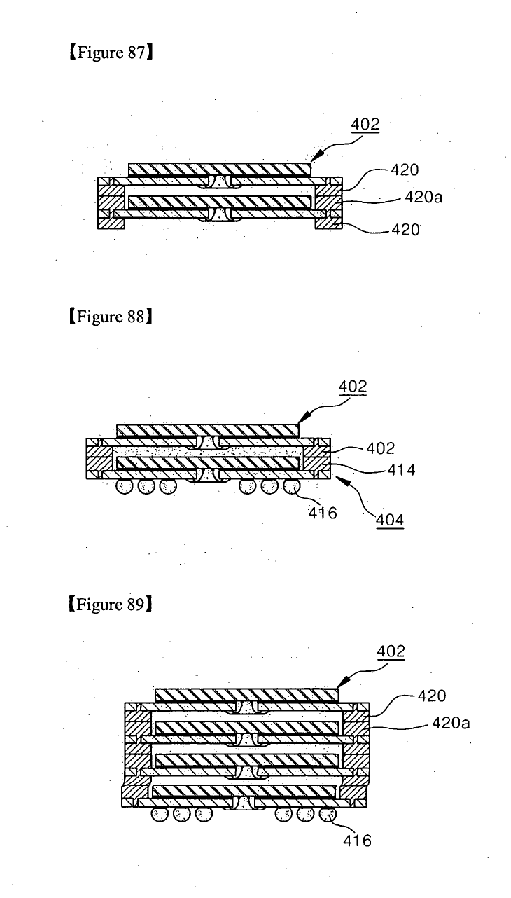

In a stacked package of FIG. 87, two BGA packages 402 of FIG. 84 are stacked, and here a conductive metallic lead 420a is installed in the upper side of the circuit board 414 of the lower side BGA package to thereby connect signals. That is, in the circuit board 414 of the lower side BGA package is installed the conductive metallic leads 420 and 420a so as to be protruded upwards and downwards.

The stacked package of FIG. 88 is formed by further installing an insulation material 430 between the stacked BGA packages in the stacked package of FIG. 86. The stacked package can be firmly fixed by means of the insulation material 430.

The stacked package of FIG. 89 is constructed in such a manner that the BGA packages of FIGS. 84 and 85 are stacked in multi-layered form, and the signal connection between the staked BGA packages is achieved by means of the conductive metallic leads 420 and 420a, which is protruded upwards and downwards of the circuit board 414.

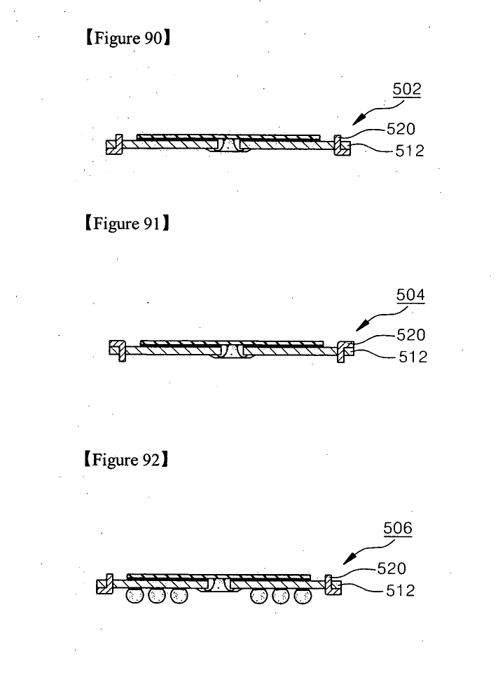

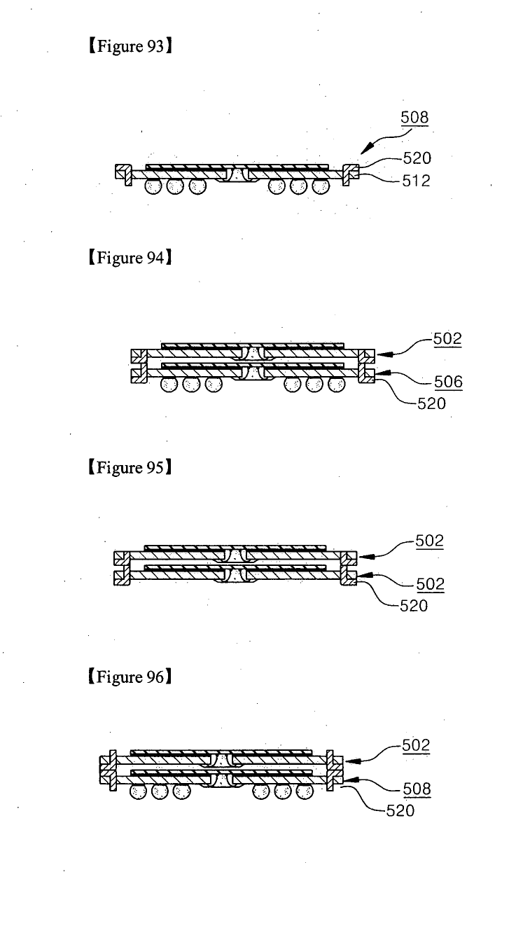

FIGS. 90 to 93 are cross-sections each showing a BGA package to be used in a stacked package according to a fourteenth embodiment of the invention.

Referring to FIGS. 90 to 93, in the BGA packages 502 to 508 to be used for the fourteenth embodiment, a bent-formed conductive metallic lead 520 is installed in such a way as to pass through a circuit board 512 at a position near the edge area of the circuit board 512, similar to the BGA packages used in the thirteenth embodiment of the invention. However, a difference is in that the conductive metallic lead is bent.

FIGS. 94 to 97 are cross-sections each showing a tacked package according to a fourteenth embodiment of the invention, where the BGA packages of FIGS. 90 to 93 are used.

Similar to the thirteenth embodiment of the invention, the stacked packages of fourteenth embodiment is formed using the BGA packages of FIGS. 90 to 93. The BGA packages of FIGS. 90 to 93 may be used for constructing various other types of stacked packages, which are not illustrated in FIGS. 94 to 97.

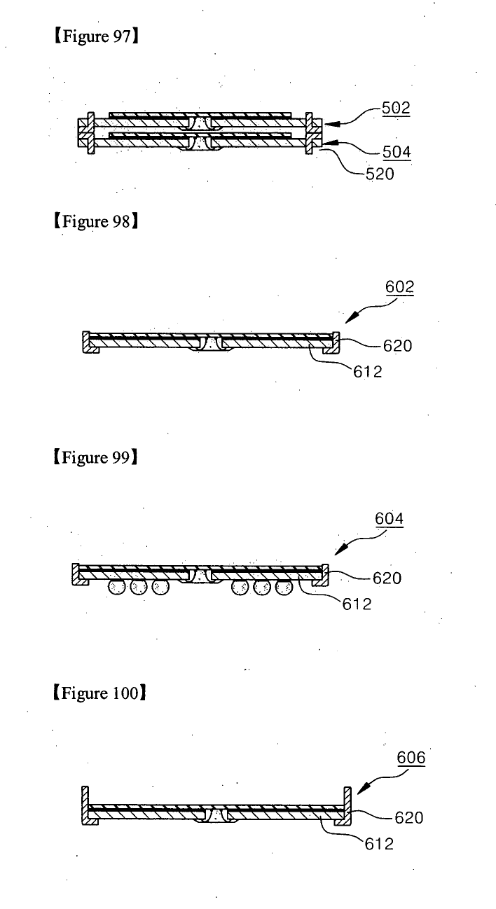

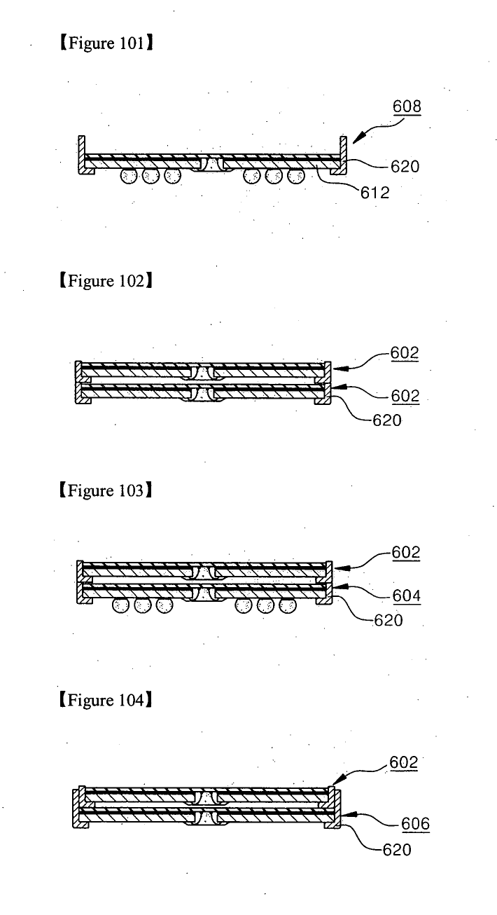

FIGS. 98 to 101 are cross-sections each showing a BGA packages to be used in a stacked package according to a fifteenth embodiment of the invention.

Referring to FIGS. 98 to 101, in the BGA packages 602 to 608 to be used for the fifteenth embodiment, a bent-formed conductive metallic lead 620 is installed in the edge area of the circuit board 612, similar to the BGA packages used in the fourteenth embodiment of the invention. However, a difference is in that the conductive metallic lead 612 is bonded to the edge, instead of passing through the circuit board.

In addition, dissimilar to the previous embodiment, the conductive metallic lead 620 adhered to the edge of the circuit board 612 is extended to the extent that it can be protruded upwardly or downwardly. The conductive metallic lead 620 protruded upwards or downward of the circuit board 612 functions to transmit signals of the stacked packages and also, in case where it is protruded downwardly, can be served as an input/output terminal. When it is used as an input/output terminal, the solder ball does not need to be installed on the bottom surface of the circuit board 612.

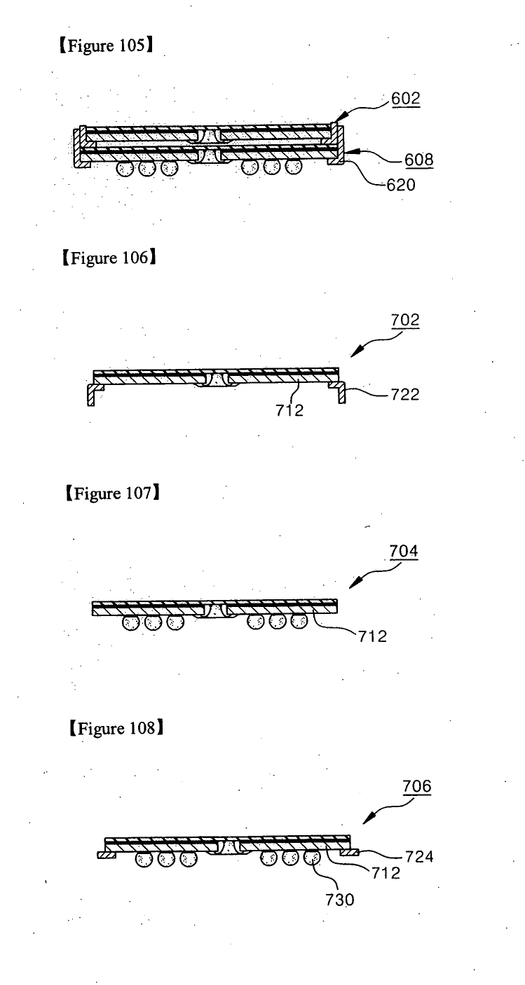

FIGS. 102 to 105 are cross-sections each showing a stacked package according to a fifteenth embodiment of the invention, where the BGA packages of FIGS. 98 to 101 are used.

Similar to the fourteenth embodiment of the invention, the stacked packages of fifteenth embodiment are formed using the BGA packages of FIGS. 98 to 101. The BGA packages of FIGS. 98 to 101 may be used for constructing various other types of stacked packages, which are not illustrated in FIGS. 102 to 105.

FIGS. 106 to 109 are cross-sections each showing a BGA package to be used in a stacked package according to a sixteenth embodiment of the invention.

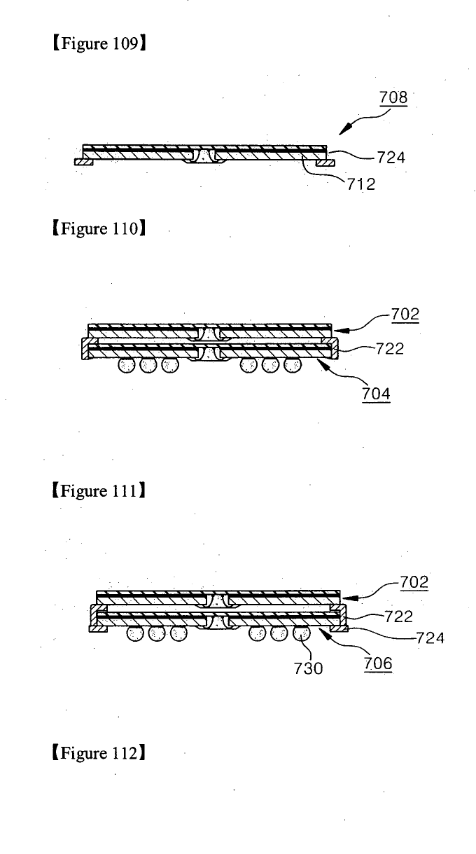

In the BGA packages 702 to 708 used for constructing a stacked package of sixteenth embodiment, near the edge area of the circuit board 712 provided in the packages 702 to 708, a bent-formed conductive metallic lead 722 may be installed, as shown in FIG. 106, or a flat conductive metallic lead 724 may be installed, as shown in FIGS. 108 and 109. Or they may be a common package where a conductive metallic lead is not installed. In particular, when the flat conductive metallic lead 724 is installed, a solder ball 730 may be installed, as shown in FIG. 108, or may not be installed, as shown in FIG. 109.

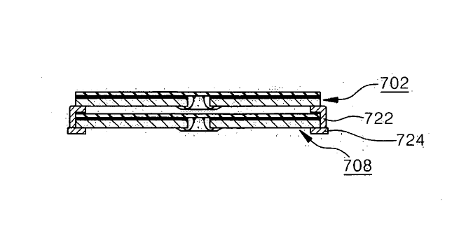

FIGS. 110 to 112 are cross-sections each showing a stacked package according to a sixteenth embodiment of the invention, where the BGA packages of FIGS. 106 to 109 are used.

As illustrated in the figures, the stacked packages of sixteenth embodiment are formed using the BGA packages of FIGS. 106 to 109, and have a signal transmission function through a conductive metallic lead. The BGA packages of FIGS. 106 to 109 may be arranged and stacked so as to construct various other types of stacked packages, which are not illustrated in FIGS. 110 to 112.

As describe above, in the stacked package according to the present invention, a conductive metallic lead (also known as a lead frame) or a gold wire is used as a signal connection member for transmitting signals of stacked BGA packages, thereby shortening the signal processing time. In addition, the conductive metallic lead is installed in a plating hole or a pad provided in the circuit board so as to transmit signals.

As apparent from the above description, according to the present invention, the height of a stacked package can be reduced and simultaneously shorten the signal length between BGA packages, thereby enabling the fabrication of high-speed stacked packages.

Furthermore, in the stacked package of the invention, a soldering can be carried out from outside, thereby enabling an easy fabrication and visual inspection, and also a mass production, which leads to reduction in the manufacturing cost.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

1. A stacked package comprising:
a) two or more of a first BGA package and a second BGA package;
b) a circuit board having a circuit pattern, the first BGA package being mounted on one face of the circuit board, the second BGA package being mounted on the other face of the circuit board; and
c) a signal connection member for transmitting signals of the first BGA package and the second BGA package to each other, the second BGA package being provided with a signal connection pad, one end of the signal connection member being bonded to the signal connection pad and the other end of the signal connection member being bonded to the circuit pattern of the circuit board.

2. The stacked package according to claim 1, Wherein the signal connection member is provided with an insulation material coated in the entire periphery thereof.

3. The stacked package according to claim 1, wherein the signal connection member is formed of a gold wire or a bent-formed conductive metallic lead.

4. The stacked package according to claim 1, wherein the circuit board is further provided with a signal connection-plating hole connected with a circuit pattern thereof, and the signal connection member is connected in such a way to be inserted and bonded into the signal connection-plating hole.

5. A stacked package comprising:
a) two or more of a first BGA package and a second BGA package;
b) a first circuit board having a circuit pattern, the first BGA package being mounted on one face of the first circuit board, the second BGA package being mounted on the other face of the first circuit board;
c) a second circuit board having a circuit pattern, the second BGA package stacked in the first circuit board being surface-mounted on either face of the second circuit board;
d) a signal connection member for transmitting signals of the first BGA package and the second BGA package to each other, both ends of the signal connection member being bonded to the respective circuit patterns of the first and second circuit boards; and
e) a solder ball installed in the bottom surface of the second circuit board, for inputting and outputting signals of the first and second BGA packages.

6. The stacked package according to claim 5, wherein the signal connection member is provided with an insulation material coated in the entire periphery thereof.

7. The stacked package according to claim 5, wherein the signal connection member is formed of a gold wire or a bent-formed conductive metallic lead.

8. The stacked package according to claim 5, wherein either one or both of the first circuit board and the second circuit board are further provided with a signal connection-plating hole connected with a circuit pattern thereof, and the signal connection member is connected in such a way as to be inserted and bonded into the signal connection-plating hole.

9. A stacked package comprising two or more stacked packages according to claim 5 stacked in multi-layered form, and a signal connection connector installed between the stacked layers for connecting signals of the layered stacked packages.

10. A stacked package comprising:
a) a first and second BGA package each having a circuit board, the circuit board having either a signal connection pad or a signal connection-plating hole each provided near an edge area thereof; and
b) a signal connection member for transmitting signals of the first and second BGA packages which are stacked, the signal connection member being formed of a conductive metallic lead, the conductive metallic lead being bonded to the signal connection pad and being inserted and then bonded into the signal connection-plating hole so as to connect signals of the first and second BGA packages.

11. The stacked package according to claim 10, wherein an insulation material is inserted between the stacked first and second BGA packages.

12. The stacked package according to claim 10, wherein the conductive metallic lead is bent-formed so as to protrude upwards or downwards of the circuit board.

13. The stacked package according to claim 10, wherein the signal connection member is installed in each of the first and second BGA packages, and the first and second BGA packages are stacked in such a manner that the signal connection members are bonded to each other to thereby transmit signals.

14. The stacked package according to claim 10, further comprising a third circuit board installed in the lowest end of the stacked first and second BGA packages, the third circuit board including a circuit pattern for transmitting signals, of the first and second BGA packages and either one of a signal connection pad or a signal connection-plating hole to be connected with the circuit pattern, the signal connection pad or the signal connection-plating hole being connected with the signal connection member so as to transmit signals.

15. The stacked package according to claim 14, wherein the third circuit board has a solder ball installed in the bottom surface thereof, for inputting and outputting signals of the first and second BGA packages.

16. A method of fabricating a staked package, the method comprising steps of:
a) providing a second BGA package having a signal connection pad;
b) providing a circuit board having a circuit pattern capable of connecting a signal of the second BGA package;
c) placing an adhesive on one face of the circuit board and attaching the second BGA package at desired intervals;
d) connecting the signal connection pad of the second BGA package with the circuit pattern of the circuit board using a signal connection member, the signal connection member being selected from a gold wire and a bent-formed conductive metallic lead;
e) surface-mounting a first BGA package on the opposite face to the second BGA package in the circuit board so as to be connected with the circuit pattern thereof; and
f) cutting the circuit board into each piece of stacked package.

17. The method according to claim 16, after the connecting step, further comprising a step of coating an insulation material in the entire periphery of the signal connection member to thereby protect the signal connection member.

18. A method of fabricating a stacked package, the method comprising steps of:
a) providing a second BGA package;
b) providing a first circuit board having a circuit pattern capable of connecting a signal of the second BGA package;
c) placing an adhesive on one face of the first circuit board and attaching the second BGA package at desired intervals;
d) cutting into each piece the first circuit board having the second BGA packages attached thereto;
e) providing a second circuit board having a circuit pattern capable of connecting a signal of the second BGA package, to which the first circuit board is attached;
f) placing an adhesive on one face of the second circuit board and attaching at desired intervals the second BGA package, to which the first circuit board is attached;
g) connecting the circuit patterns provided in the first and second circuit boards using a signal connection member, the signal connection member being selected from a gold wire and a bent-formed conductive metallic lead;
h) surface-mounting a first BGA package on the first circuit board so as to be electrically connected with the circuit pattern thereof, the first circuit board having the second BGA package attached thereto;
i) fusion-bonding a solder ball in the bottom surface of the second circuit board so as to enable a signal input/output; and
j) cutting the second circuit board into each piece.

19. The method according to claim 18, after the connecting step, further comprising a step of coating an insulation material in the entire periphery of the signal connection member to thereby protect the signal connection member.
